(19) United States
(12) Patent Application Publication
(10) Pub. No.: US 2026/0105939 A1
(43) Pub. Date: Apr. 16, 2026

(54) MEMORY DEVICES CONFIGURED IN CFET STRUCTURES AND METHODS FOR MANUFACTURING THE SAME

(71) Applicant: Taiwan Semiconductor Manufacturing Company, Ltd., Hsinchu (TW)

(72) Inventors: Jui-Lin Chen, Hsinchu City (TW); Yung-Ting Chang, Hsinchu City (TW); Lien-Jung Hung, Hsinchu City (TW)

(73) Assignee: Taiwan Semiconductor Manufacturing Company, Ltd., Hsinchu (TW)

(21) Appl. No.: 19/170,950

(22) Filed: Apr. 4, 2025

Related U.S. Application Data
(60) Provisional application No. 63/705,660, filed on Oct. 10, 2024.

(51) Int. Cl. G11C 5/06; H10B 10/00; H10D 30/00; H10D 30/01; H10D 30/43; H10D 62/10; H10D 84/01; H10D 84/85

(52) U.S. Cl. CPC G11C 5/063; H10B 10/12; H10D 30/014; H10D 30/0191; H10D 30/43; H10D 30/502; H10D 62/121; H10D 84/0186; H10D 84/851

(57) ABSTRACT

A memory device includes a substrate having a first side and a second side; a first transistor, a second transistor, a third transistor, and a fourth transistor formed on the first side, the first to fourth transistors each formed with a p-type conductivity; a fifth transistor and a sixth transistor formed on the first side and over the first to fourth transistors, the fifth to sixth transistors each formed with an n-type conductivity; a first interconnect structure formed on the first side and over the fifth to sixth transistors, and coupled to the first transistor, wherein the first interconnect structure is configured as a portion of a first bit line; and a second interconnect structure formed on the second side, and also coupled to the first transistor, wherein the second interconnect structure is configured as another portion of the first bit line.

### CROSS-REFERENCE TO RELATED APPLICATION

This application claims priority to and the benefit of U.S. Provisional Application No. 63/705,660, filed Oct. 10, 2024, entitled “DUAL SIDE DOUBLE DATA LINES IN CFET SRAM,” which is incorporated herein by reference in its entirety for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example circuit diagram of a memory cell, in accordance with some embodiments.

FIGS. 2-5 illustrate layouts that are collectively configured to form the memory cell of FIG. 1 in a CFET structure, in accordance with some embodiments.

FIG. 6 illustrates a cross-sectional view of a semiconductor device formed based on the layouts of FIGS. 2-5, in accordance with some embodiments.

FIG. 7 illustrates an example circuit diagram of another memory cell, in accordance with some embodiments.

FIGS. 8-11 illustrate layouts that are collectively configured to form the memory cell of FIG. 7 in a CFET structure, in accordance with some embodiments.

FIGS. 12 and 13 illustrate respective block diagrams of memory circuits, each including multiple memory arrays, in accordance with some embodiments.

FIGS. 14 and 15 illustrate layouts that are collectively configured to form the memory cell of FIG. 1 in a CFET structure, in accordance with some embodiments.

FIG. 16 illustrates a cross-sectional view of a semiconductor device formed based on the layouts of FIGS. 14-15, in accordance with some embodiments.

FIG. 17 illustrates an example flow chart of a method for forming a semiconductor device including a memory cell configured with a CFET structure, in accordance with some embodiments.

FIGS. 18-26 illustrate cross-sectional views of an example semiconductor device during various fabrication stages, made by the method of FIG. 17, in accordance with some embodiments.

FIG. 27 illustrates an example flow chart of a method for forming a semiconductor device including a memory cell configured with a CFET structure, in accordance with some embodiments.

FIGS. 28-38 illustrate cross-sectional views of an example semiconductor device during various fabrication stages, made by the method of FIG. 27, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Complementary field-effect transistors (CFETs) are one type of gate-all-around (GAA) field-effect transistors. In general, a GAA FET includes a plural number of nanostructures, such as nanosheets or nanowires, vertically stacked on top of one another. P-type and n-type GAA FETs are formed on the same horizontal plane over a substrate and are separated by isolation structures. In contrast, a CFET is commonly fabricated by vertically stacking a p-type GAA FET and an n-type GAA FET on top of each other. This stacking configuration of n-type and p-type transistors in a single structure eliminates the need for an n-to-p separation, reduces the active area footprint, and increases the transistor density within a chip. This stacking concept is not limited to GAA FETs; for example, CFETs can be formed with FinFET devices or with a combination of GAA FETs and FinFETs.

It has been proposed to form static random access memory (SRAM) cells based on the CFET structures. For example, to form an SRAM cell with six transistors (6T) which is generally referred to as a 6T SRAM cell, a first level including a number of p-type transistors is first formed on the frontside of a substrate, followed by a second level including a number of n-type transistors formed over the first level (on the frontside of the substrate). Generally, the existing SRAM cell have its pull-up transistors formed with the n-type conductivity, i.e., the pull-up transistors being formed at the second level. As such, data lines (e.g., a bit line BL/bit line bar BLB) of the SRAM cell are typically restricted to form on one side of the substrate. For example, the bit lines BLs (and BLBs) of the existing memory cell configured with the CFET structure are commonly formed as metal tracks at a third frontside level, sometimes referred to as a metallization layer. However, in accordance with the scaling trend (e.g., leading to a narrower metal width and/or narrower metal spacing), parasitic resistance and/or capacitance of such “one-sided” data lines can disadvantageously increase. This can negatively impact overall performance of the memory cells. Thus, the existing CFET structures configured for forming memory cells have not been entirely satisfactory in certain aspects.

The present disclosure provides various embodiments of a semiconductor device (e.g., a memory device) formed in a CFET structure that has first and second frontside levels over a substrate for forming respectively different conductive types of transistors. According to various embodiments of the present disclosure, the memory device may include plural SRAM cells, each of which includes plural (e.g., 6) transistors. In one aspect, the SRAM cell, as disclosed herein, can include first and second p-type pass-gate transistors and first and second p-type pull-up transistors formed at the first frontside level, and first and second n-type pull-down transistors formed at the second frontside level. In another aspect, the SRAM cell, as disclosed herein, can include first and second p-type pass-gate transistors and first and second p-type pull-down transistors formed at the first frontside level, and first and second n-type pull-up transistors formed at the second frontside level. With the p-type pass-gate transistors formed at the first level, bit lines BLs (and BLBs) of the disclosed memory device can each be formed on both sides of the substrate. For example, each of the BLs can be formed of at least a first metal track disposed in a third frontside level and a second metal track disposed in a first backside level, where the first and second metal tracks can be electrically connected to each other through at least a vertical contact structure and an epitaxial structure of the pass-gate transistor. By forming the bit line BL (or BLB) with at least two metal tracks, parasitic resistance of the bit line BL (or BLB) can be significantly reduced. Such a BL/BLB formed of multiple metal tracks on the frontside and the backside is sometimes referred to as a dual-side data line. As a result, overall performance of the disclosed memory device can still be improved, even following the scaling trend.

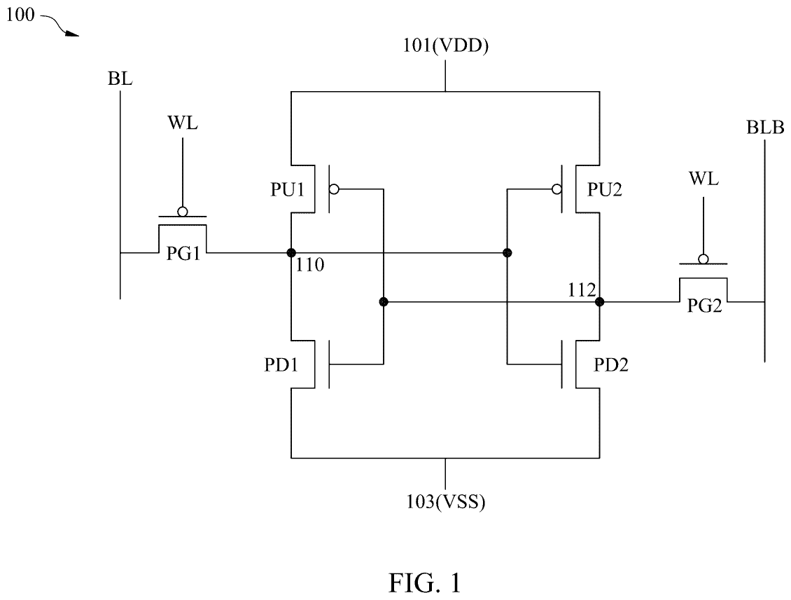

FIG. 1 illustrates an example circuit diagram of a memory cell 100, in accordance with some embodiments. As shown, the memory cell 100 includes six transistors that operatively form a 6T SRAM cell. In various embodiments of the present disclosure, these six transistors can be physically formed with a CFET structure, which will be discussed below. For example, the memory cell 100 includes transistors: a first pull-up transistor PU1, a second pull-up transistor PU2, a first pull-down transistor PD1, a second pull-down transistor PD2, a first pass-gate transistor PG1, and a second pass-gate transistor PG2.

The transistors PU1 and PD1 are formed as a first inverter and the transistors PU2 and PD2 are formed as a second inverter, wherein the first and second inverters are cross coupled to each other. For example, the transistors PU1 and PD1 have their respective source/drain terminals connected to each other at internal node 110, which is further coupled to gate terminals of the transistors PU2 and PD2; and the transistors PU2 and PD2 have their respective source/drain terminals connected to each other at internal node 112, which is further coupled to gate terminals of the transistors PU1 and PD1. Specifically, the first and second inverters are each coupled between first voltage reference 201 and second voltage reference 103. In some embodiments, the first voltage reference 201 is a supply voltage applied to the memory cell 100, sometimes referred to as “VDD,” and the second voltage reference 103 is a ground voltage, sometimes referred to as “VSS.” The first inverter (formed by the transistors PU1 and PD1) is coupled to the transistor PG1 which is gated by a word line (WL), and the second inverter (formed by the transistors PU2 and PD2) is coupled to the transistor PG2 which is also gate by the WL. Further, the transistor PG1 is coupled between a bit line (BL) and the node 110, and the transistor PG2 is coupled between a bit line bar (BLB) and the node 112.

With their gate terminals each coupled to the WL, the transistors PG1 and PG2 are configured to receive a pulse signal through the WL, to allow or block an access (e.g., a read operation, a write operation) of the memory cell 100 accordingly. The transistors PD1 and PU1 are coupled between VDD and VSS, and coupled to each other at node 110. For example, the transistor PU1 has a first source/drain terminal connected to VDD and the transistor PD1 has a first source/drain terminal connected to VSS, with the transistors PU1 and PD1 having their second source/drain terminals connected to each other at the node 110. The transistor PG1 has a first source/drain terminal connected to the BL and a second source/drain terminal connected to the node 110, which is further coupled to gate terminals of the transistors PU2 and PD2. Similarly, the transistors PD2 and PU2 are coupled between VDD and VSS, and coupled to each other at the node 112. For example, the transistor PU2 has a first source/drain terminal connected to VDD and the transistor PD2 has a first source/drain terminal connected to VSS, with the transistors PU2 and PD2 having their second source/drain terminals connected to each other at the node 112. The transistor PG2 has a first source/drain terminal connected to the BLB and a second source/drain terminal connected to the node 112, which is further coupled to gate terminals of the transistors PU1 and PD1.

In some embodiments, the transistors PU1, PU2, PG1, and PG2 each include a p-type metal-oxide-semiconductor (PMOS) transistor, and the transistors PD1 and PD2 each include an n-type metal-oxide-semiconductor (NMOS) transistor. Although the illustrated embodiment of FIG. 1 shows that the transistors of the memory cell 100 are either NMOS or PMOS transistors, any of a variety of transistors or devices that are suitable for use in a memory device may be implemented as at least one of the transistors of the memory cell 100 such as, for example, a bipolar junction transistor (BJT), a high-electron-mobility transistor (HEMT), etc. Further, as will be discussed below, the p-type transistors, PU1, PU2, PG1, and PG2, are each formed as a GAA FET in a first level disposed on the frontside of a substate, and the n-type transistors, PD1 and PD2, are each formed as a GAA FET in a second level over the first level.

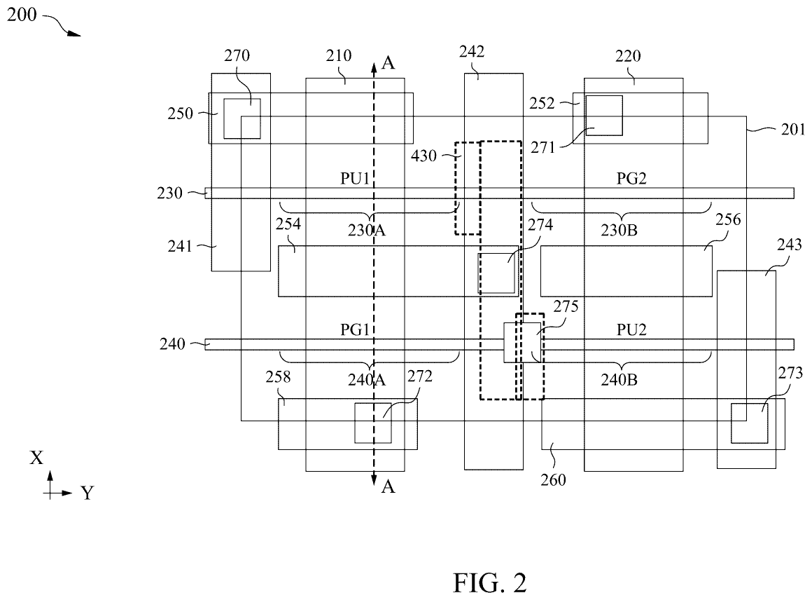

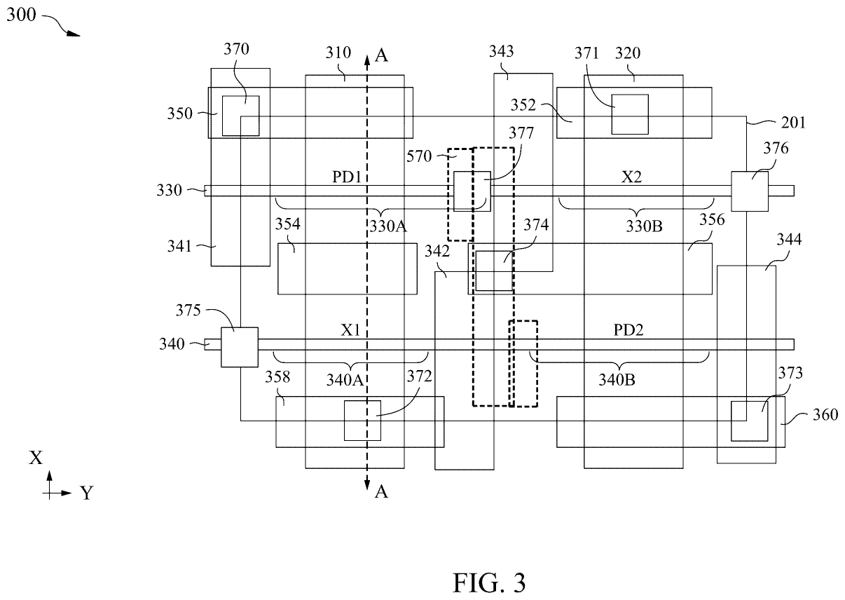

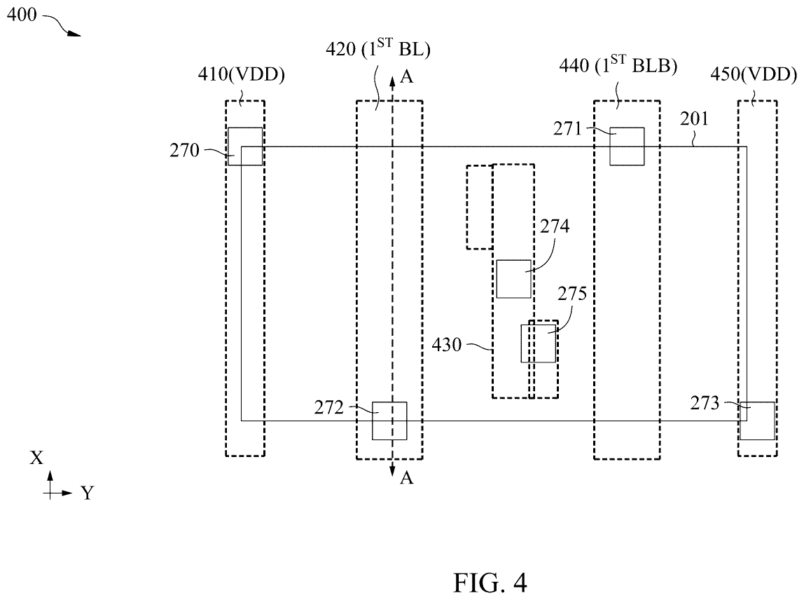

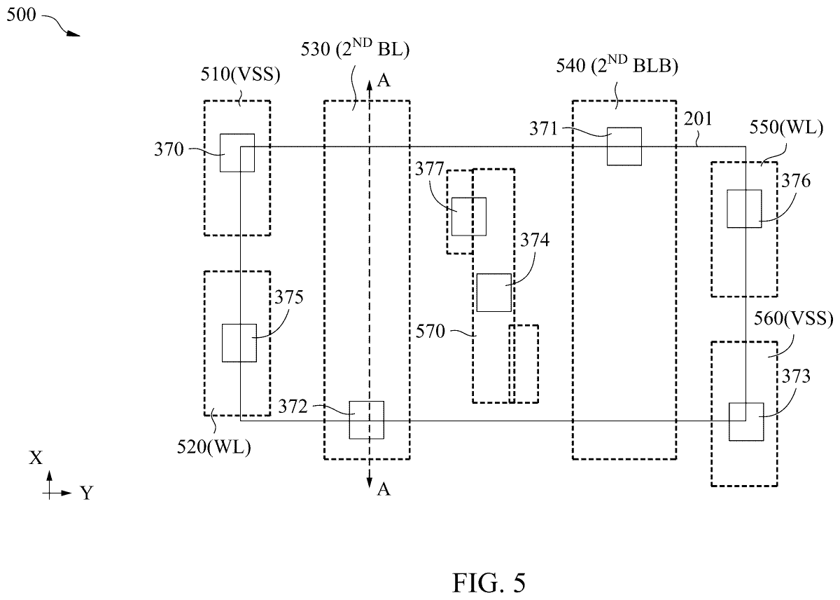

FIG. 2, FIG. 3, FIG. 4, and FIG. 5 respectively illustrate layouts 200, 300, 400, and 500 that can be collectively utilized to form the memory cell 100 (FIG. 1) configured in a CFET structure. It should be understood that each of the layouts 200 to 500 has been simplified for illustrative purposes, and thus, can include any of various other patterns (or structures) while remaining within the scope of the present disclosure.

As depicted, each of the layouts 200 to 500 includes a cell boundary 201 defining a physical area for the memory cell 100, which can include six transistors configured with a CFET structure. The CFET structure can include a number of first transistors disposed at a first level on the frontside of a substate, and a number of second transistors despised at a second, upper level on the frontside of the substrate. In some embodiments, each of these first and second transistors is configured as a GAA FET, while the first transistors and the second transistors have opposite conductive types. In some other embodiments, each of the first and second transistors can be formed as other type of transistor structures while remaining within the scope of the present disclosure.

Generally, each of the layouts 200 to 500 can include a number of patterns configured for forming respective structures, and thus, such patterns of the disclosed layout are herein referred to as the structures to be formed, respectively, in the following discussion. For example, the layout 200 is configured to form structures of the first transistors at the first level on the frontside; the layout 300 is configured to form structures of the second transistors at the second level on the frontside; the layout 400 is configured to form the structures at a third level on the frontside of the substrate, over the second level; and the layout 500 is configured to form the structures at a first level on a backside of the substrate.

Referring first to FIG. 2, the layout 200 can include patterns for forming active regions 210 and 220, and gate structures 230 and 240, respectively. The active regions 210 and 220 may extend in the X-direction; and the gate structures 230 and 240 may extend in the Y-direction. Each of the active regions 210 and 220 may be formed as a fin structure or a stack structure extending along the X-direction, and each of the gate structures 230 and 240 may be formed to extend in the Y-direction to traverse the active regions 210 and 220. The layout 200 can further include a number of cut patterns, e.g., 241, 242, and 243, each of which can extend along the X-direction traversing one or more of the gate structures 230 and 240. The cut patterns 241 to 243 can each be configured to form a dielectric structure, thereby dividing one or more of the gate structures 230 and 240 into separate gate sections. For example, the cut pattern 242 can divide the gate structure 230 into gate sections 230A and 230B, and divide the gate structure 240 into gate sections 240A and 240B, as indicated in FIG. 2.

Referring next to FIG. 3, the layout 300 can include patterns for forming active regions 310 and 320, and gate structures 330 and 340, respectively. The active regions 310 and 320 may extend in the X-direction; and the gate structures 330 and 340 may extend in the Y-direction. Each of the active regions 310 and 320 may be formed as a fin structure or a stack structure extending along the X-direction, and each of the gate structures 330 and 340 may be formed to extend in the Y-direction to traverse the active regions 310 and 320. The layout 300 can further include a number of cut patterns, e.g., 341, 342, 343, and 344, each of which can extend along the X-direction traversing one or more of the gate structures 330 and 340. The cut patterns 341 to 344 can each be configured to form a dielectric structure, thereby dividing one or more of the gate structures 330 and 340 into separate gate sections. For example, the cut pattern 342 can divide the gate structure 340 into gate sections 340A and 340B, and the cut pattern 343 can divide the gate structure 330 into gate sections 330A and 330B, as indicated in FIG. 3.

In some embodiments, the active regions 210 and 310 are vertically aligned with each other, the active regions 220 and 320 are vertically aligned with each other, the gate structures 230 and 330 are vertically aligned with each other, and the gate structures 240 and 340 are vertically aligned with each other. Further, the cut patterns 241 and 341 are vertically aligned with each other, the cut patterns 242 and 342 are vertically aligned with each other, and the cut patterns 243 and 343 are vertically aligned with each other. The active regions 210 and 310 may be physically formed as a single structure (sometimes referred to as “active region 210/310”), the active regions 220 and 320 may be physically formed as a single structure (sometimes referred to as “active region 220/320”), the gate structures 230 and 330 may be physically formed as a single structure (sometimes referred to as “gate structure 230/330”), and the gate structures 240 and 340 may be physically formed as a single structure (sometimes referred to as “gate structure 240/340”).

As will be discussed below, each of the gate structures 230/330 and 240/340 can include a lower portion and an upper portion, corresponding to the first level and the second level, respectively, where the lower portion and the upper portion are electrically coupled to each other even with a dielectric layer vertically interposed therebetween. Stated another way, the corresponding dielectric layer can partially separate the lower and upper portion of each of the gate structures 230/330 and 240/340, while the lower portion and upper portion may remain electrically coupled to each other.

For example, the active region 210/310 and active region 220/320 can each be first formed as a stack structure protruding from the frontside surface of a substrate. The stack may include a number of first semiconductor nanostructures (e.g., first nanosheets) extending along the X-direction and vertically separated from each other, and a number of second semiconductor nanostructures (e.g., second nanosheets) extending along the X-direction and vertically separated from each other. The first nanosheets are positioned at the first level, and the second nanosheets are positioned at the second level. According to some embodiments of the present disclosure, the first nanosheets, formed based on a lower portion of the active region 210/310 or a lower portion of the active region 220/320, can partially form the first transistors formed at the first level; and the second nanosheets, formed based on an upper portion of the active region 210/310 or an upper portion of the active region 220/320, can partially form the second transistors formed at the second level. Further, the first nanosheets and the second nanosheets can be vertically aligned with but separated from each other, with at least one dielectric layer interposed therebetween.

Next, respective portions of the first and second nanosheets in each of the stacks that are overlaid by the gate structures 230/330 and 240/340, which are initially formed as a number of dummy (e.g., polysilicon) gate structures, respectively, may remain. Other portions of the first nanosheets are replaced with a number of first epitaxial structures, and other portions of the second nanosheets are replaced with a number of second epitaxial structures. According to some embodiments of the present disclosure, the first epitaxial structures (at the first level) may be formed with a p-type conductivity, and the second epitaxial structures (at the second level) may be formed with an n-type conductivity. The first epitaxial structures can operatively form respective source/drain terminals of the first transistors at the first level, and the second epitaxial structures can operatively form respective source/drain terminals of the second transistors at the second level.

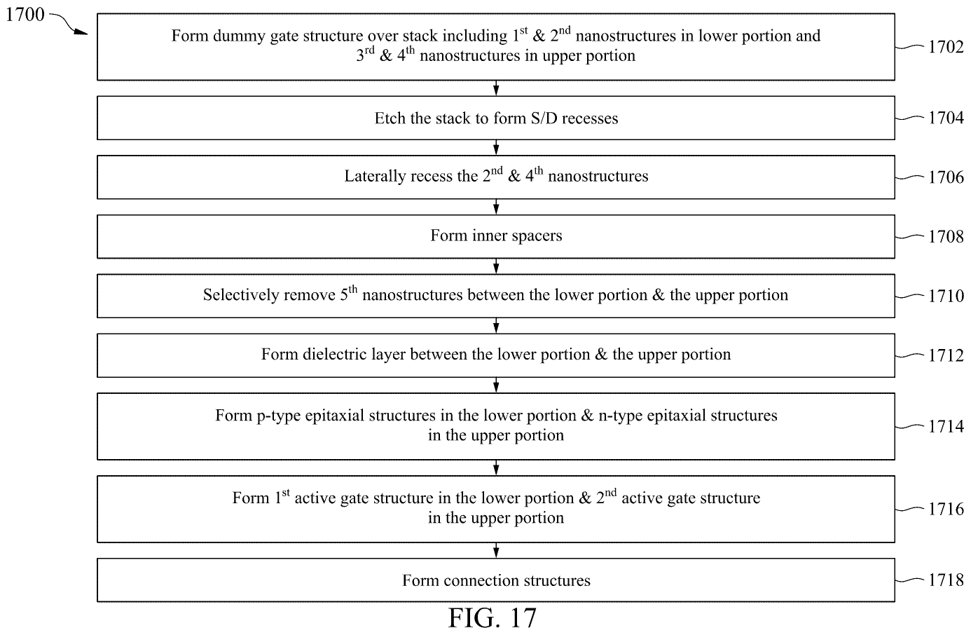

Next, each of the dummy gate structures 230/330 and 240/340 can be replaced by a corresponding active (e.g., metal) gate structure to form the first and second transistors. As mentioned above, each of the active gate structures can include a lower portion and an upper portion corresponding to the first level and the second level, respectively. Further, the lower and upper portion of each of the active gate structures 230/330 and 240/340 may be electrically coupled to each other. For example, the lower portion of the active gate structure may include one or more first work function metals configured for forming a gate terminal of one of the first transistors with the p-type conductivity, and the upper portion of the active gate structure may include one or more second work function metals configured for forming a gate terminal of one of the second transistors with the n-type conductivity. Details of a series of manufacturing processes to form the structures of the first transistors at the first level and the second transistors at the second level will be described with respect to FIGS. 17-38.

As a brief overview, the transistors PU1, PU2, PG1, and PG2 of the memory cell 100 can be formed at the first level based on the layout 200 (as indicated in FIG. 2), and the transistors PD1 and PD2 of the memory cell 100 can be formed at the second level based on the layout 300 (as indicated in FIG. 3). Further, a pair of dummy transistors can be formed at the second level (indicated by symbolic “X1” and “X2” in FIG. 3). One of the source/drain terminals of each of the dummy transistors X1 and X2 can be replaced by one or more dielectric layers, and a vertical contact structure can be formed to extend through the dielectric layer(s), which will be discussed below. In some embodiments, the transistors PU1, PU2, PG1, and PG2 at the first level can be formed with the p-type conductivity, and the transistors PD1 and PD2 at the second level can be formed with the n-type conductivity.

For example, in FIG. 2, the transistor PU1 can include its channel, gate terminal, and source/drain terminals formed by a subset of the first nanosheets in the active region 210, the gate section 230A, and a subset of the first epitaxial structures formed from the active region 210 and disposed on opposite sides of the gate section 230A, respectively. The transistor PU2 can include its channel, gate terminal, and source/drain terminals formed by another subset of the first nanosheets in the active region 220, the gate section 240B, and another subset of the first epitaxial structures formed from the active region 220 and disposed on opposite sides of the gate section 240B, respectively. The transistor PG1 can include its channel, gate terminal, and source/drain terminals formed by yet another subset of the first nanosheets in the active region 210, the gate section 240A, and yet another subset of the first epitaxial structures formed from the active region 210 and disposed on opposite sides of the gate section 240A, respectively. The transistor PG2 can include its channel, gate terminal, and source/drain terminals formed by yet another subset of the first nanosheets in the active region 220, the gate section 230B, and yet another subset of the first epitaxial structures formed from the active region 210 and disposed on opposite sides of the gate section 230B, respectively.

In FIG. 3, the transistor PD1 can include its channel, gate terminal, and source/drain terminals formed by a subset of the second nanosheets in the active region 310, the gate section 330A, and a subset of the second epitaxial structures formed from the active region 310 and disposed on opposite sides of the gate section 330A, respectively. The transistor PD2 can include its channel, gate terminal, and source/drain terminals formed by another subset of the second nanosheets in the active region 320, the gate section 340B, and another subset of the second epitaxial structures formed from the active region 320 and disposed on opposite sides of the gate section 340B, respectively. The dummy transistor X1 can include its channel, gate terminal, and source/drain terminals formed by another subset of the second nanosheets in the active region 310, the gate section 340A, and another subset of the second epitaxial structures formed from the active region 310 and disposed on opposite sides of the gate section 340A, respectively. The dummy transistor X2 can include its channel, gate terminal, and source/drain terminals formed by a subset of the second nanosheets in the active region 320, the gate section 330B, and a subset of the second epitaxial structures formed from the active region 320 and disposed on opposite sides of the gate section 330B, respectively.

Referring again to FIG. 2, the layout 200 can further include patterns for forming source/drain contact structures 250, 252, 254, 256, 258, and 260, respectively. Similarly in FIG. 3, the layout 300 can further include patterns for forming source/drain contact structures 350, 352, 354, 356, 358, and 360, respectively. Such source/drain contact structures 250 to 260 and 350 to 360 are each sometimes referred to as MD. In general, each of these MDs 250 to 260 and 350 to 360 is configured to electrically connect to the source/drain terminal of a corresponding transistor. For example, each of the MDs 250 to 260 and 350 to 360 can be physically coupled to or wrap around the epitaxial structure of a corresponding transistor. In some embodiments, each of the MDs 250 to 260 and 350 to 360 can laterally extend along the same direction as the gate structures 230-240 and 330-340, e.g., the Y-direction.

For example, in FIG. 2, the MD 250 is connected to the first source/drain terminal of the transistor PU1; the MD 254 is connected to the second source/drain terminal of the transistor PU1 and the second source/drain terminal of the transistor PG1; the MD 258 is connected to the first source/drain terminals of the transistor PG1; the MD 252 is connected to the first source/drain terminal of the transistor PG2; the MD 256 is connected to the second source/drain terminal of the transistor PG2 and the second source/drain terminal of the transistor PU2; and the MD 260 is connected to the first source/drain terminals of the transistor PU2. In FIG. 3, the MD 350 is connected to the first source/drain terminal of the transistor PD1; the MD 354 is connected to the second source/drain terminal of the transistor PD1 and one of the source/drain terminals of the first dummy transistor X1; the MD 358 is connected to the other source/drain terminal of the first dummy transistor X1; the MD 352 is connected to one of the source/drain terminals of the second dummy transistor X2; the MD 356 is connected to the other source/drain terminal of the second dummy transistor X2 and the second source/drain terminal of the transistor PD2; and the MD 360 is connected to the first source/drain terminals of the transistor PD2.

In some embodiments, the MD 254 (FIG. 2) and MD 354 (FIG. 3) may be connected to each other through a first internal via structure (not shown), and the MD 256 (FIG. 2) and MD 356 (FIG. 3) may be connected to teach other through a second internal via structure (not shown). Stated another way, the first internal via structure can vertically extend from the first level to the second level to connect the MD 254 to the MD 354, and the second internal via structure can vertically extend from the first level to the second level to connect the MD 256 to the MD 356. As such, the (internal) node 112 of the memory cell 100, at which the respective source/drain terminals of the transistors PU2, PD2, and PG2 are connected to one another, can be partially formed based on the MD 256, the MD 356, and the second internal via structure vertically interposed therebetween; and the (internal) node 110 of the memory cell 100, at which the respective source/drain terminals of the transistors PU1, PD1, and PG1 are connected to one another, can be operatively formed based on the MD 254, the MD 354, and the first internal via structure vertically interposed therebetween.

Referring again to FIG. 2, the layout 200 can further include patterns for forming a number of first via structures 270, 271, 272, 273, and 274, and a second via structure 275, respectively. In some embodiments, each of the via structures 270 to 274 can be formed below an MD included in the layout 200. Particularly, the via structures 270 to 274 can each downwardly extend from the frontside of the substrate (e.g., the first level on the frontside) to the backside of the substrate (e.g., the first level on the backside). Such via structures 270 to 274 are each sometimes referred to as a BVD. The via structure 275 can be formed below a gate structure (or gate section) included in the layout 200. Particularly, the via structure 275 can downwardly extend from the frontside of the substrate (e.g., the first level on the frontside) to the backside of the substrate (e.g., the first level on the backside). Such a via structure 275 is sometimes referred to as a BVG.

For example, the BVD 270 is formed below the MD 250, allowing the MD 250 to be electrically connected to one or more interconnect structures formed in the first level on the backside (e.g., an interconnect structure configured as a first power rail carrying the supply voltage VDD for the memory cell 100, which is formed based on the layout 400); the BVD 271 is formed below the MD 252, allowing the MD 252 to be electrically connected to one or more interconnect structures formed in the first level on the backside (e.g., an interconnect structure configured as a first portion of the BLB of the memory cell 100, which is formed based on the layout 400); the BVD 272 is formed below the MD 258, allowing the MD 258 to be electrically connected to one or more interconnect structures formed in the first level on the backside (e.g., an interconnect structure configured as a first portion of the BL of the memory cell 100, which is formed based on the layout 400); and the BVD 273 is formed below the MD 260, allowing the MD 260 to be electrically connected to one or more interconnect structures formed in the first level on the backside (e.g., an interconnect structure configured as a second power rail carrying the supply voltage VDD for the memory cell 100, which is formed based on the layout 400).

The BVG 275 is formed below the gate section 240B, allowing the gate section 240B to be electrically connected to one or more interconnect structures formed in the first level on the backside (e.g., an interconnect structure configured as a first internal contact structure for the memory cell 100, which is formed based on the layout 400). Such a first internal contact structure 430 (FIG. 4) is also shown in FIG. 2 with a dotted line, as a reference. The BVD 274 is formed below the MD 254, allowing the MD 254 to be electrically connected to the first internal contact structure 430. In some embodiments, the first internal contact structure 430 may be formed with a zigzag profile, e.g., having a relatively long portion extending in the X-direction and a pair of relatively short portion protruding toward opposite directions along the Y-direction, which will be discussed in detail below with respect to FIG. 4.

Similarly, the layout 300 can further include patterns for forming a number of first via structures 370, 371, 372, 373, and 374, and a number of second via structures 375, 376, and 377, respectively. In some embodiments, each of the via structures 370 to 374 can be formed above an MD included in the layout 300. Particularly, the via structures 370 to 374 can each upwardly extend from the second level on the frontside to a next upper level (e.g., the third level on the frontside). Such via structures 370 to 374 are each sometimes referred to as a VD. Each of the via structure 375 to 377 can be formed above a gate structure (or gate section) included in the layout 300. Particularly, the via structures 375 to 377 can upwardly extend from the second level on the frontside to a next upper level (e.g., the third level on the frontside). Such via structures 375 to 377 are each sometimes referred to as a VG.

For example, the VD 370 is formed above the MD 350, allowing the MD 350 to be electrically connected to one or more interconnect structures formed in the third level on the frontside (e.g., an interconnect structure configured as a first power rail carrying the ground voltage VSS for the memory cell 100, which is formed based on the layout 500); the VD 371 is formed above the MD 352, allowing the MD 352 to be electrically connected to one or more interconnect structures formed in the third level on the frontside (e.g., an interconnect structure configured as a second portion of the BLB of the memory cell 100, which is formed based on the layout 500); the VD 372 is formed above the MD 358, allowing the MD 358 to be electrically connected to one or more interconnect structures formed in the third level on the frontside (e.g., an interconnect structure configured as a second portion of the BL of the memory cell 100, which is formed based on the layout 500); and the VD 373 is formed above the MD 360, allowing the MD 360 to be electrically connected to one or more interconnect structures formed in the third level on the frontside (e.g., an interconnect structure configured as a second power rail carrying the ground voltage VSS for the memory cell 100, which is formed based on the layout 500).

The VG 375 is formed above the gate section 340A, allowing the gate section 340A (and the gate section 240A physically disposed below and electrically connected to the gate section 340A) to be electrically connected to one or more interconnect structures formed in the third level on the frontside (e.g., an interconnect structure configured as a first portion of the WL of the memory cell 100, which is formed based on the layout 500); and the VG 376 is formed above the gate section 330B, allowing the gate section 330B (and the gate section 230B physically disposed below and electrically connected to the gate section 330B) to be electrically connected to one or more interconnect structures formed in the third level on the frontside (e.g., an interconnect structure configured as a second portion of the WL of the memory cell 100, which is formed based on the layout 500).

The VG 377 is formed above the gate section 330A, allowing the gate section 330A to be electrically connected to one or more interconnect structures formed in the third level on the frontside (e.g., an interconnect structure configured as a second internal contact structure for the memory cell 100, which is formed based on the layout 500). Such a second internal contact structure 570 (FIG. 5) is also shown in FIG. 3 with a dotted line, as a reference. The VD 374 is formed below the MD 356, allowing the MD 356 to be electrically connected to the second internal contact structure 570. In some embodiments, the second internal contact structure 570 may be formed with a zigzag profile, e.g., having a relatively long portion extending in the X-direction and a pair of relatively short portion protruding toward opposite directions along the Y-direction, which will be discussed in detail below with respect to FIG. 5.

Referring next to FIG. 4, the layout 400 can include patterns for forming interconnect structures 410, 420, 430, 440, and 450 in the first level on the backside, respectively. The first level, disposed on the backside, may sometimes be referred to as a bottommost one of plural backside metallization layers, e.g., BM0 layer, and the interconnect structures 410 to 450 disposed therein are each sometimes referred to as a BM0 track. The backside metallization layer typically includes one or more dielectric materials (e.g., silicon oxide, a low-k dielectric material, or the like) embedding the corresponding metal tracks formed of, e.g., copper. These BM0 tracks can extend along the same direction as the active regions 210-220 and 310-320, e.g., the X-direction.

In some embodiments, the BM0 tracks 410 to 450, except the BM0 track 430, can each be coupled to a corresponding one of the overlaying MDs in the first level on the frontside through a BVD. For example, the BM0 track 410 is coupled to the MD 250 (FIG. 2) through the BVD 270; the BM0 track 420 is coupled to the MD 258 (FIG. 2) through the BVD 272; the BM0 track 540 is coupled to the MD 252 (FIG. 2) through the BVD 271; and the BM0 track 450 is couped to the MD 260 (FIG. 2) through the BVD 273. In some embodiments, the BM0 track 430 is coupled to the gate section 240B and the MD 254 through the BVG 275 and the BVD 274, respectively. For example, the relatively long portion of the BM0 track 430, extending in the X-direction, can overlap with the MD 254 that extends in the Y-direction, and the relatively short portion of the BM0 track 430, protruding away from the long portion along the Y-direction, can overlap with the gate section 240B.

The BM0 track 410 can operatively serve the first power rail carrying the supply voltage VDD for the memory cell 100; the BM0 track 420 can operatively serve as the first portion of the BL of the memory cell 100; the BM0 track 440 can operatively serve as the first portion of the BLB of the memory cell 100; and the BM0 track 450 can operatively serve as the second power rail carrying the supply voltage VDD for the memory cell 100. Further, the BM0 track 430 can serve as the above-mentioned first internal contact structure for the memory cell 100. For example, the BM0 track 430 can electrically couple the gate terminal of the transistor PU2 (also the gate terminal of the transistor PD2) to the commonly connected second source/drain terminals of the transistors PU1 and PG1, which is further coupled to the second source/drain terminal of the transistor PD1, e.g., through the above-described first internal via structure that connects the MD 254 to the MD 354.

Referring then to FIG. 5, the layout 500 can include patterns for forming interconnect structures 510, 520, 530, 540, 550, 560, and 570 in the third level on the frontside, respectively. The third level, disposed on the frontside, may sometimes be referred to as a bottommost one of plural frontside metallization layers, e.g., M0 layer, and the interconnect structures 510 to 570 disposed therein are each sometimes referred to as an M0 track. The frontside metallization layer typically includes one or more dielectric materials (e.g., silicon oxide, a low-k dielectric material, or the like) embedding the corresponding metal tracks formed of, e.g., copper. These M0 tracks can extend along the same direction as the active regions 210-220 and 310-320, e.g., the X-direction.

In some embodiments, the M0 tracks 510 to 570, except the M0 track 570, can each be coupled to a corresponding one of the underlying MDs in the second level on the frontside through a VD or a corresponding one of the underlying gate structures (gate sections) in the second level on the frontside through a VG. For example, the M0 track 510 is coupled to the MD 350 (FIG. 3) through the VD 370; the M0 track 520 is coupled to the gate section 340A (FIG. 3) through the VG 375; the M0 track 530 is coupled to the MD 358 (FIG. 3) through the VD 372; the M0 track 540 is coupled to the MD 352 (FIG. 3) through the VD 371; the M0 track 550 is couped to the gate section 330B (FIG. 3) through the VG 376; and the M0 track 560 is coupled to the MD 360 (FIG. 3) through the VD 373. In some embodiments, the M0 track 570 is coupled to the gate section 330A and the MID 356 through the VG 377 and the VD 374, respectively. For example, the relatively long portion of the M0 track 570, extending in the X-direction, can overlap with the MD 356 that extends in the Y-direction, and the relatively short portion of the M0 track 570, protruding away from the long portion along the Y-direction, can overlap with the gate section 330A.

The M0 track 510 can operatively serve the first power rail carrying the ground voltage VSS for the memory cell 100; the M0 track 520 can operatively serve as a first portion of the WL of the memory cell 100; the M0 track 530 can operatively serve as the second portion of the BL of the memory cell 100; the M0 track 540 can operatively serve as the second portion of the BLB of the memory cell 100; the M0 track 550 can operatively serve as a second portion of the WL of the memory cell 100; and the M0 track 560 can operatively serve as the second power rail carrying the ground voltage VSS for the memory cell 100. Further, the BM0 track 570 can serve as the above-mentioned second internal contact structure for the memory cell 100. For example, the M0 track 570 can electrically couple the gate terminal of the transistor PD1 (also the gate terminal of the transistor PU1) to the second source/drain terminal of the transistor PD2, which is further coupled to the commonly connected second source/drain terminals of the transistors PU2 and PG2, e.g., through the above-described second internal via structure that connects the MD 256 to the MD 356.

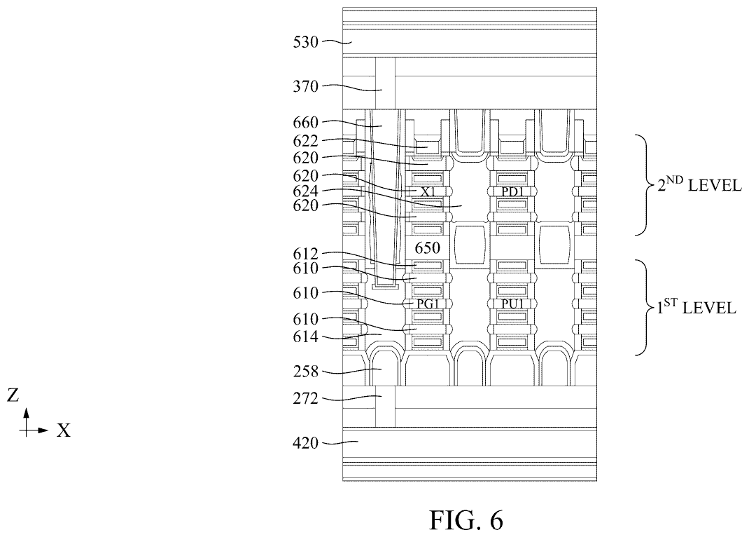

FIG. 6 illustrates a cross-sectional view of a portion of a semiconductor device formed based on the layouts 200-500 (FIGS. 2-5), in accordance with some embodiments. For example, the cross-sectional view of FIG. 6 is cut along line A-A, as indicated in FIGS. 2-5. Specifically, the line A-A extends along the active region 210 of FIG. 2, the active region 310 of FIG. 3, the BM0 track 420 of FIG. 4, and M0 track 530 of FIG. 5.

As depicted, the transistors PU1 and PG1 are formed at the first level on the frontside of a substrate, and the transistors X1 and PD1 are formed at the second level over the first level. The transistors PD1 and PUI are vertically aligned with each other; and the transistors X1 and PG1 are vertically aligned with each other. In some embodiments, the transistors PU1 and PG1 are formed with p-type, by each having its source/drain terminals formed as p-type epitaxial structures and its gate terminal (or active gate structure) formed with one or more p-type work function metals; and the transistors X1 and PD1 are formed with n-type, by each having its source/drain terminals formed as n-type epitaxial structures and its gate terminal (or active gate structure) formed with one or more n-type work function metals.

Using the vertically aligned transistor X1 and transistor PG1 as a representative example, the transistor PG1 has a number of nanosheets 610 operatively configured as its channel, p-type epitaxial structures 614 operatively configured as its source/drain terminals, and gate structure 612 operatively configured as its gate terminal; and the transistor X1 has a number of nanosheets 620 operatively configured as its channel, one n-type epitaxial structure 624 operatively configured as its source/drain terminal, and gate structure 622 operatively configured as its gate terminal.

Each of the nanosheets 610 is wrapped by the gate structure 612 that can include a gate dielectric and one or more p-type work function metals, and has its ends coupled to a pair of the p-type epitaxial structures 614, respectively. Each of the nanosheets 620 is wrapped by the gate structure 622 that can include a gate dielectric and one or more n-type work function metals, and has one of its ends coupled to the n-type epitaxial structure 624. The gate structure 612 and the gate structure 622 are electrically coupled to each other, with a dielectric layer 650 interposed therebetween. Stated another way, the gate structure 612 and the gate structure 622 respectively have first portions in contact with each other, and second portions in contact with the dielectric layer 650, which may be visible in another cross-sectional view perpendicular to the cross-sectional view of FIG. 6.

In some embodiments of the present disclosure, one of the n-type epitaxial structures 624 of the transistor X1 can be partially replaced with a vertical contact structure 660, as shown in FIG. 6. The vertical contact structure 660 may be electrically isolated from the neighboring nanosheets, e.g., 620, with one or more dielectric layers. Such dielectric layers can be formed prior to the formation of the vertical contact structure 660. For example, after the formation of the n-type epitaxial structures 624 of the transistor X1, one of the epitaxial structures 624 is removed (e.g., etched) to form an opening that may expose the underlying p-type epitaxial structure 614. The opening is filled with the one or more dielectric layers (e.g., silicon oxide, silicon nitride, or combinations thereof). Next, an anisotropic etching process may be performed to again expose the underlying p-type epitaxial structure 614, followed by filling the re-formed opening with a metal material (e.g., tungsten, cobalt, titanium, tantalum, nickel, aluminum, copper, or combinations thereof).

Accordingly, the vertical contact structure 660 can vertically extend through the second frontside level to connect the source/drain terminal of the transistor PG1 (one of the p-type epitaxial structures 614 that remains) to the VD 372. For example, the vertical contact structure 660 can have a bottom surface in contact with the source/drain terminal of the transistor PG1 and a top surface in contact with the VD 372. The source/drain terminal of the transistor PG1 is electrically connected to the MD 258, which is electrically connected to the BVD 272, which is electrically connected to the BM0 track 420; and the VD 372 is electrically connected to the M0 track 530.

With the vertical contact structure 660, the BM0 track 420, which operatively serves as the first portion of the BL, and the M0 track 530, which operatively serves as the second portion of the BL, can be electrically coupled to each other. Equivalently, the memory cell 100 can have at least a pair of BLs formed on the frontside and the backside of the substrate, respectively, which can advantageously reduce parasitic resistance of the BL. Despite not shown, it should be appreciated that the memory cell can have its BLB formed as a first metal track and a second metal track disposed on the frontside and the backside of the substrate, respectively.

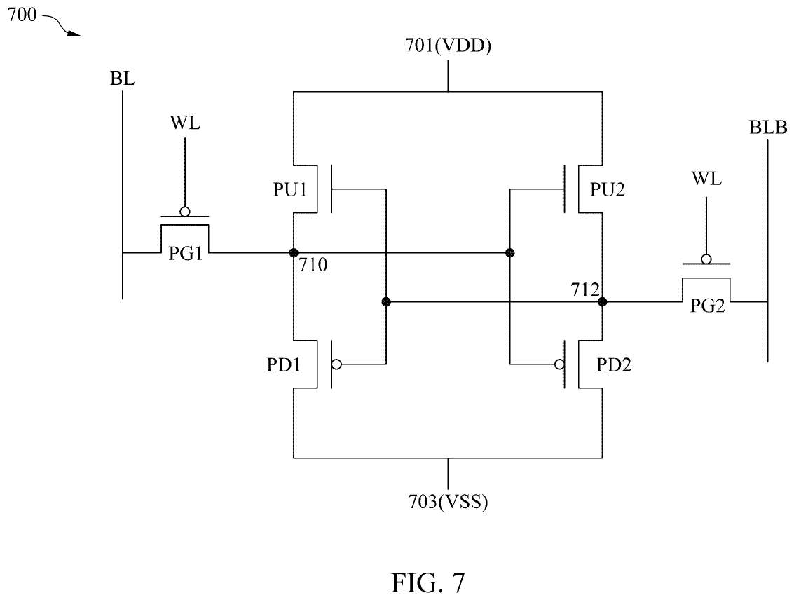

FIG. 7 illustrates an example circuit diagram of another memory cell 700, in accordance with some embodiments. As shown, the memory cell 700 includes six transistors that operatively form a 6T SRAM cell. In various embodiments of the present disclosure, these six transistors can be physically formed with a CFET structure, which will be discussed below. For example, the memory cell 700 includes transistors: a first pull-up transistor PU1, a second pull-up transistor PU2, a first pull-down transistor PD1, a second pull-down transistor PD2, a first pass-gate transistor PG1, and a second pass-gate transistor PG2.

The transistors PU1 and PD1 are formed as a first inverter and the transistors PU2 and PD2 are formed as a second inverter, wherein the first and second inverters are cross coupled to each other. For example, the transistors PU1 and PD1 have their respective source/drain terminals connected to each other at internal node 710, which is further coupled to gate terminals of the transistors PU2 and PD2; and the transistors PU2 and PD2 have their respective source/drain terminals connected to each other at internal node 712, which is further coupled to gate terminals of the transistors PU1 and PD1. Specifically, the first and second inverters are each coupled between first voltage reference 801 and second voltage reference 703. In some embodiments, the first voltage reference 801 is a supply voltage applied to the memory cell 700, sometimes referred to as “VDD,” and the second voltage reference 703 is a ground voltage, sometimes referred to as “VSS.” The first inverter (formed by the transistors PU1 and PD1) is coupled to the transistor PG1 which is gated by a word line (WL), and the second inverter (formed by the transistors PU2 and PD2) is coupled to the transistor PG2 which is also gate by the WL. Further, the transistor PG1 is coupled between a bit line (BL) and the node 710, and the transistor PG2 is coupled between a bit line bar (BLB) and the node 712.

With their gate terminals each coupled to the WL, the transistors PG1 and PG2 are configured to receive a pulse signal through the WL, to allow or block an access (e.g., a read operation, a write operation) of the memory cell 700 accordingly. The transistors PD1 and PU1 are coupled between VDD and VSS, and coupled to each other at node 710. For example, the transistor PU1 has a first source/drain terminal connected to VDD and the transistor PD1 has a first source/drain terminal connected to VSS, with the transistors PU1 and PD1 having their second source/drain terminals connected to each other at the node 710. The transistor PG1 has a first source/drain terminal connected to the BL and a second source/drain terminal connected to the node 710, which is further coupled to gate terminals of the transistors PU2 and PD2. Similarly, the transistors PD2 and PU2 are coupled between VDD and VSS, and coupled to each other at the node 712. For example, the transistor PU2 has a first source/drain terminal connected to VDD and the transistor PD2 has a first source/drain terminal connected to VSS, with the transistors PU2 and PD2 having their second source/drain terminals connected to each other at the node 712. The transistor PG2 has a first source/drain terminal connected to the BLB and a second source/drain terminal connected to the node 712, which is further coupled to gate terminals of the transistors PU1 and PD1.

In some embodiments, the transistors PD1, PD2, PG1, and PG2 each include a p-type metal-oxide-semiconductor (PMOS) transistor, and the transistors PU1 and PU2 each include an n-type metal-oxide-semiconductor (NMOS) transistor. Although the illustrated embodiment of FIG. 7 shows that the transistors of the memory cell 700 are either NMOS or PMOS transistors, any of a variety of transistors or devices that are suitable for use in a memory device may be implemented as at least one of the transistors of the memory cell 700 such as, for example, a bipolar junction transistor (BJT), a high-electron-mobility transistor (HEMT), etc. Further, as will be discussed below, the p-type transistors, PD1, PD2, PG1, and PG2, are each formed as a GAA FET in a first level disposed on the frontside of a substate, and the n-type transistors, PU1 and PU2, are each formed as a GAA FET in a second level over the first level.

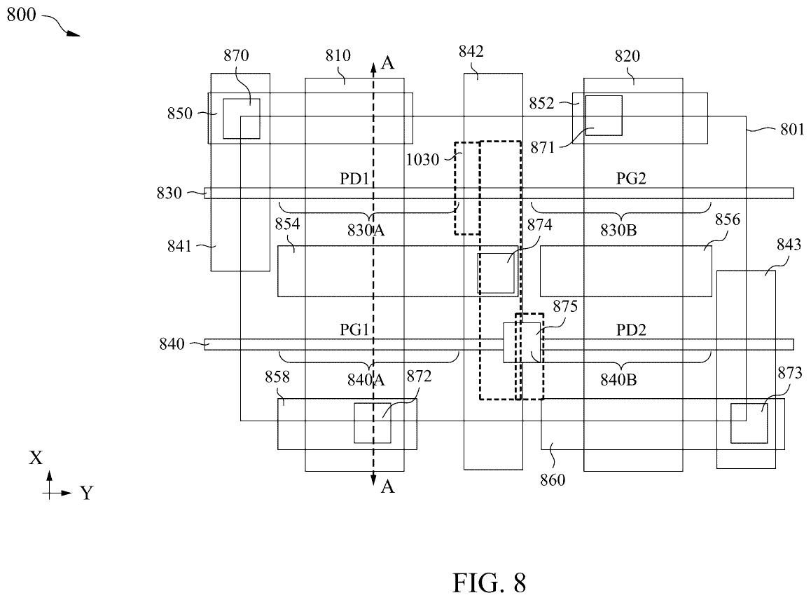

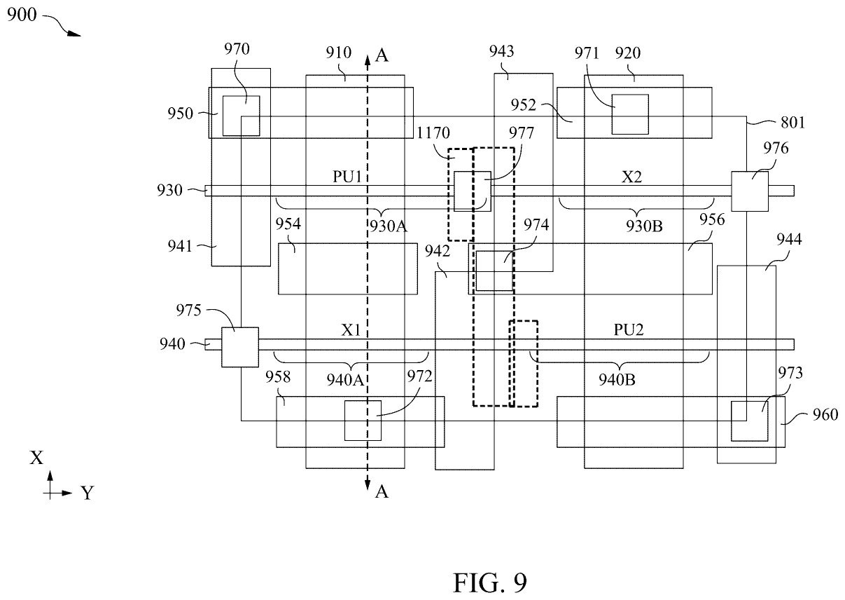

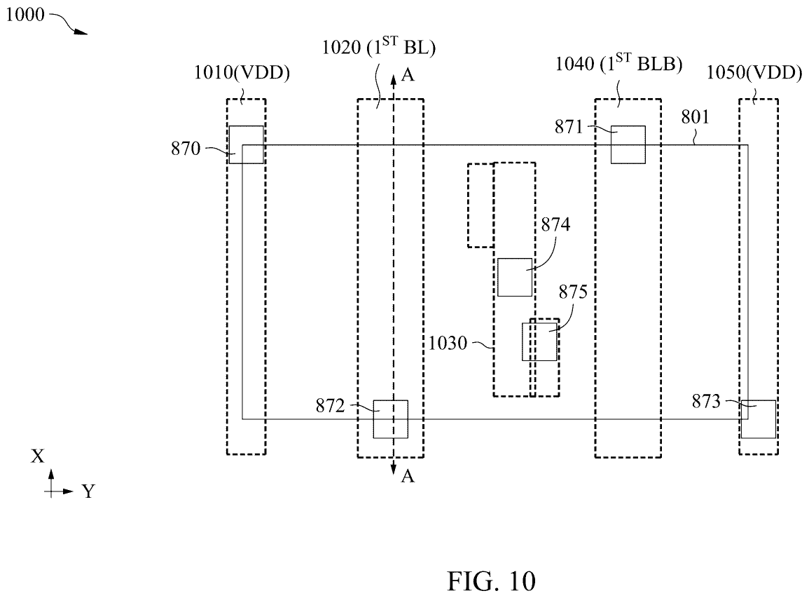

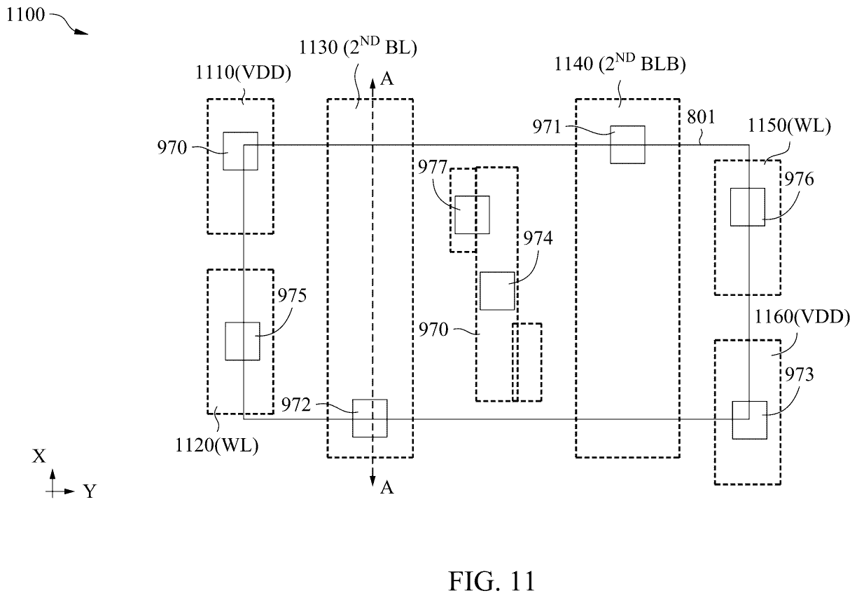

FIG. 8, FIG. 9, FIG. 10, and FIG. 11 respectively illustrate layouts 800, 900, 1000, and 1100 that can be collectively utilized to form the memory cell 700 (FIG. 7) configured in a CFET structure. It should be understood that each of the layouts 800 to 1100 has been simplified for illustrative purposes, and thus, can include any of various other patterns (or structures) while remaining within the scope of the present disclosure.

As depicted, each of the layouts 800 to 1100 includes a cell boundary 801 defining a physical area for the memory cell 700, which can include six transistors configured with a CFET structure. The CFET structure can include a number of first transistors disposed at a first level on the frontside of a substate, and a number of second transistors despised at a second, upper level on the frontside of the substrate. In some embodiments, each of these first and second transistors is configured as a GAA FET, while the first transistors and the second transistors have opposite conductive types. In some other embodiments, each of the first and second transistors can be formed as other type of transistor structures while remaining within the scope of the present disclosure.

Generally, each of the layouts 800 to 1100 can include a number of patterns configured for forming respective structures, and thus, such patterns of the disclosed layout are herein referred to as the structures to be formed, respectively, in the following discussion. For example, the layout 800 is configured to form structures of the first transistors at the first level on the frontside; the layout 900 is configured to form structures of the second transistors at the second level on the frontside; the layout 1000 is configured to form the structures at a third level on the frontside of the substrate, over the second level; and the layout 1100 is configured to form the structures at a first level on a backside of the substrate.

Referring first to FIG. 8, the layout 800 can include patterns for forming active regions 810 and 820, and gate structures 830 and 840, respectively. The active regions 810 and 820 may extend in the X-direction; and the gate structures 830 and 840 may extend in the Y-direction. Each of the active regions 810 and 820 may be formed as a fin structure or a stack structure extending along the X-direction, and each of the gate structures 830 and 840 may be formed to extend in the Y-direction to traverse the active regions 810 and 820. The layout 800 can further include a number of cut patterns, e.g., 841, 842, and 843, each of which can extend along the X-direction traversing one or more of the gate structures 830 and 840. The cut patterns 841 to 843 can each be configured to form a dielectric structure, thereby dividing one or more of the gate structures 830 and 840 into separate gate sections. For example, the cut pattern 842 can divide the gate structure 830 into gate sections 830A and 830B, and divide the gate structure 840 into gate sections 840A and 840B, as indicated in FIG. 8.

Referring next to FIG. 9, the layout 900 can include patterns for forming active regions 910 and 920, and gate structures 930 and 940, respectively. The active regions 910 and 920 may extend in the X-direction; and the gate structures 930 and 940 may extend in the Y-direction. Each of the active regions 910 and 920 may be formed as a fin structure or a stack structure extending along the X-direction, and each of the gate structures 930 and 940 may be formed to extend in the Y-direction to traverse the active regions 910 and 920. The layout 900 can further include a number of cut patterns, e.g., 941, 942, 943, and 944, each of which can extend along the X-direction traversing one or more of the gate structures 930 and 940. The cut patterns 941 to 944 can each be configured to form a dielectric structure, thereby dividing one or more of the gate structures 930 and 940 into separate gate sections. For example, the cut pattern 942 can divide the gate structure 940 into gate sections 940A and 940B, and the cut pattern 943 can divide the gate structure 930 into gate sections 930A and 930B, as indicated in FIG. 9.

In some embodiments, the active regions 810 and 910 are vertically aligned with each other, the active regions 820 and 920 are vertically aligned with each other, the gate structures 830 and 930 are vertically aligned with each other, and the gate structures 840 and 940 are vertically aligned with each other. Further, the cut patterns 841 and 941 are vertically aligned with each other, the cut patterns 842 and 942 are vertically aligned with each other, and the cut patterns 843 and 943 are vertically aligned with each other. The active regions 810 and 910 may be physically formed as a single structure (sometimes referred to as “active region 810/910”), the active regions 820 and 920 may be physically formed as a single structure (sometimes referred to as “active region 820/920”), the gate structures 830 and 930 may be physically formed as a single structure (sometimes referred to as “gate structure 830/930”), and the gate structures 840 and 940 may be physically formed as a single structure (sometimes referred to as “gate structure 840/940”).

As will be discussed below, each of the gate structures 830/930 and 840/940 can include a lower portion and an upper portion, corresponding to the first level and the second level, respectively, where the lower portion and the upper portion are electrically coupled to each other even with a dielectric layer vertically interposed therebetween. Stated another way, the corresponding dielectric layer can partially separate the lower and upper portion of each of the gate structures 830/930 and 840/940, while the lower portion and upper portion may remain electrically coupled to each other.

For example, the active region 810/910 and active region 820/920 can each be first formed as a stack structure protruding from the frontside surface of a substrate. The stack may include a number of first semiconductor nanostructures (e.g., first nanosheets) extending along the X-direction and vertically separated from each other, and a number of second semiconductor nanostructures (e.g., second nanosheets) extending along the X-direction and vertically separated from each other. The first nanosheets are positioned at the first level, and the second nanosheets are positioned at the second level. According to some embodiments of the present disclosure, the first nanosheets, formed based on a lower portion of the active region 810/910 or a lower portion of the active region 820/920, can partially form the first transistors formed at the first level; and the second nanosheets, formed based on an upper portion of the active region 810/910 or an upper portion of the active region 820/920, can partially form the second transistors formed at the second level. Further, the first nanosheets and the second nanosheets can be vertically aligned with but separated from each other, with at least one dielectric layer interposed therebetween.

Next, respective portions of the first and second nanosheets in each of the stacks that are overlaid by the gate structures 830/930 and 840/940, which are initially formed as a number of dummy (e.g., polysilicon) gate structures, respectively, may remain. Other portions of the first nanosheets are replaced with a number of first epitaxial structures, and other portions of the second nanosheets are replaced with a number of second epitaxial structures. According to some embodiments of the present disclosure, the first epitaxial structures (at the first level) may be formed with a p-type conductivity, and the second epitaxial structures (at the second level) may be formed with an n-type conductivity. The first epitaxial structures can operatively form respective source/drain terminals of the first transistors at the first level, and the second epitaxial structures can operatively form respective source/drain terminals of the second transistors at the second level.

Next, each of the dummy gate structures 830/930 and 840/940 can be replaced by a corresponding active (e.g., metal) gate structure to form the first and second transistors. As mentioned above, each of the active gate structures can include a lower portion and an upper portion corresponding to the first level and the second level, respectively. Further, the lower and upper portion of each of the active gate structures 830/930 and 840/940 may be electrically coupled to each other. For example, the lower portion of the active gate structure may include one or more first work function metals configured for forming a gate terminal of one of the first transistors with the p-type conductivity, and the upper portion of the active gate structure may include one or more second work function metals configured for forming a gate terminal of one of the second transistors with the n-type conductivity. Details of a series of manufacturing processes to form the structures of the first transistors at the first level and the second transistors at the second level will be described with respect to FIGS. 17-38.

As a brief overview, the transistors PD1, PD2, PG1, and PG2 of the memory cell 700 can be formed at the first level based on the layout 800 (as indicated in FIG. 8), and the transistors PU1 and PU2 of the memory cell 700 can be formed at the second level based on the layout 900 (as indicated in FIG. 9). Further, a pair of dummy transistors can be formed at the second level (indicated by symbolic “X1” and “X2” in FIG. 9). One of the source/drain terminals of each of the dummy transistors X1 and X2 can be replaced by one or more dielectric layers, and a vertical contact structure can be formed to extend through the dielectric layer(s). Such a vertical contact structure can be configured to connect a first BL formed on the frontside of the substate and a second BL formed on the backside of the substrate, as discussed above. In some embodiments, the transistors PD1, PD2, PG1, and PG2 at the first level can be formed with the p-type conductivity, and the transistors PU1 and PU2 at the second level can be formed with the n-type conductivity.

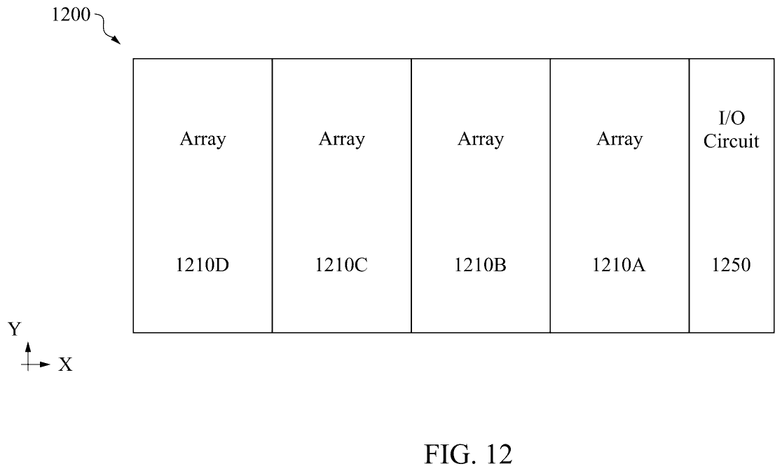

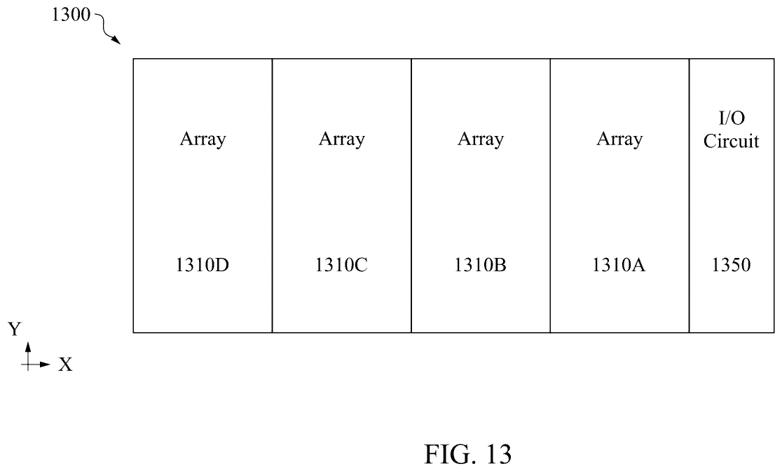

FIG. 12 and FIG. 13 respectively block diagrams of memory circuits 1200 and 1300, in accordance with some embodiments. Each of the memory circuits 1200 and 1300 can include a plural number of memory arrays, memory sub-arrays, or memory banks that share a common input/output (I/O) circuit. The I/O circuit can include a number of read/write (R/W) circuits configured to read from or write to selected memory cells of the memory arrays through one or more data lines (e.g., a corresponding pair of BL and BLB). Accordingly, the plural memory arrays may be physically arranged along a lengthwise direction of those data lines (e.g., the X-direction shown in FIGS. 12-13). Despite not shown, each of the memory arrays can be coupled to a respective WL driver through a number of access lines (e.g., WLs), and these WL drivers can be disposed with respect to the respective memory arrays along a lengthwise direction of those access lines (e.g., the Y-direction shown in FIGS. 12-13). In some embodiments, the memory array(s) disposed closer to the common I/O circuit may sometimes be referred to as near array(s), and the memory array(s) disposed farther from the common I/O circuit may sometimes be referred to as far array(s).

For example, in FIG. 12, the memory circuit 1200 includes plural memory arrays 1210A, 1210B, 1210C, 1210D, etc., that are operatively coupled to I/O circuit 1250. The memory array 1210A may be referred to as one of the near arrays, and the memory array 1210D may be referred to as one of the far arrays. In accordance with some embodiments, the memory array 1210A may have its BLs/BLBs, operatively coupled to the I/O circuit 1250, formed with the above-described dual-side data line configuration, and the memory array 1210D may also have its BLs/BLBs, operatively coupled to the I/O circuit 1250, formed with the above-described dual-side data line configuration. In FIG. 13, the memory circuit 1300 includes plural memory arrays 1310A, 1310B, 1310C, 1310D, etc., that are operatively coupled to I/O circuit 1350. The memory array 1310A may be referred to as one of the near arrays, and the memory array 1310D may be referred to as one of the far arrays. In accordance with some embodiments, the memory array 1310A may have its BLs/BLBs, operatively coupled to the I/O circuit 1350, not formed with the above-described dual-side data line configuration, while the memory array 1310D may also have its BLs/BLBs, operatively coupled to the I/O circuit 1350, formed with the above-described dual-side data line configuration.

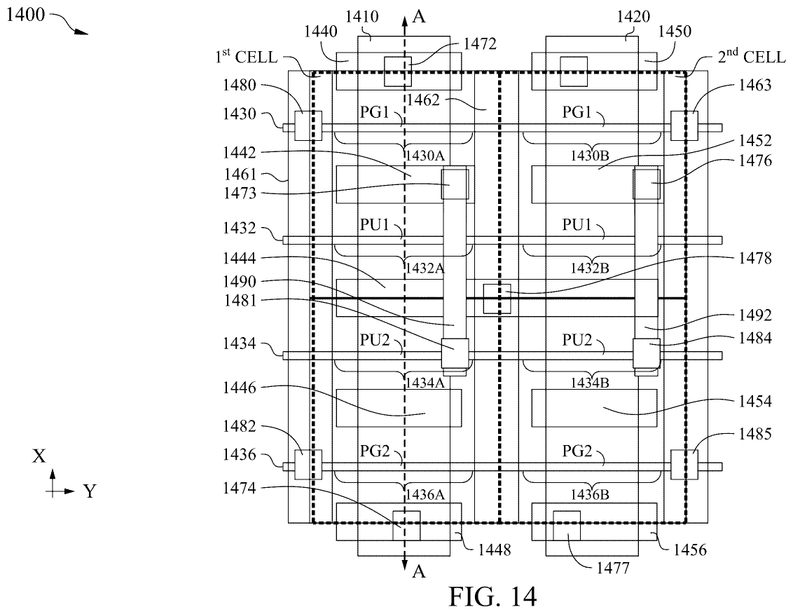

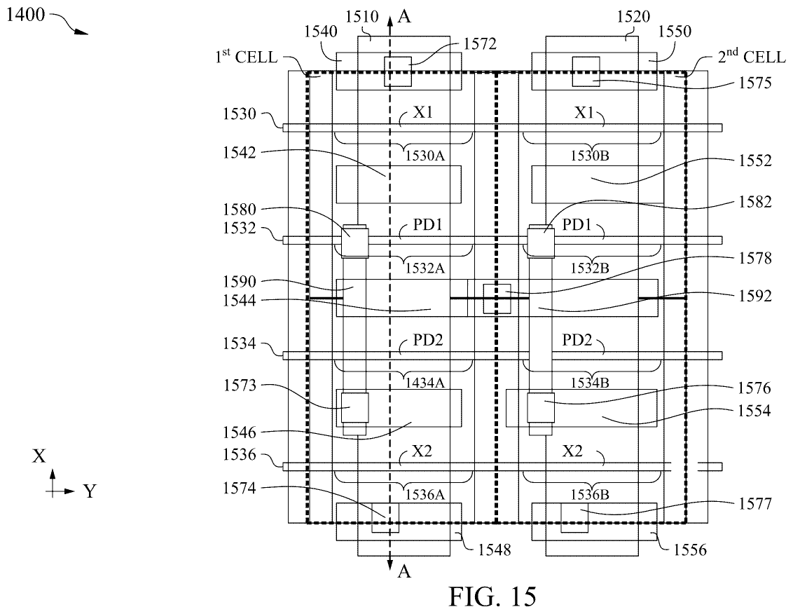

FIG. 14 and FIG. 15 respectively illustrate layouts 1400 and 1500 that can be collectively utilized to form a first memory cell and a second memory cell, each of which includes the memory cell 100 (FIG. 1) configured with a CFET structure. As depicted, each of the layouts 1400 to 1500 includes a cell boundary defining a physical area of the pair of memory cells 100. The CFET structure can include a number of first transistors disposed at a first level on the frontside of a substate, and a number of second transistors despised at a second, upper level on the frontside of the substrate. In some embodiments, each of these first and second transistors is configured as a GAA FET, while the first transistors and the second transistors have opposite conductive types. In some other embodiments, each of the first and second transistors can be formed as other type of transistor structures while remaining within the scope of the present disclosure.

Generally, each of the layouts 1400 to 1500 can include a number of patterns configured for forming respective structures, and thus, such patterns of the disclosed layout are herein referred to as the structures to be formed, respectively, in the following discussion. For example, the layout 1400 is configured to form structures of the first transistors at the first level on the frontside; and the layout 1500 is configured to form structures of the second transistors at the second level on the frontside. It should be understood that each of the layouts 1400 and 1500 has been simplified for illustrative purposes, and thus, can include any of various other patterns while remaining within the scope of the present disclosure.

Referring first to FIG. 14, the layout 1400 can include patterns for forming active regions 1410 and 1420 and gate structures 1430, 1432, 1434 and 1436, respectively. The active regions 1410 and 1420 may extend in the X-direction; and the gate structures 1430 to 1436 may extend in the Y-direction. Each of the active regions 1410 and 1420 may be formed as a fin structure or a stack structure extending along the X-direction, and each of the gate structures 1430 to 1436 may be formed to extend in the Y-direction to traverse the active regions 1410 and 1420. The layout 1400 can further include a number of cut patterns, e.g., 1461, 1462, and 1463, each of which can extend along the X-direction traversing the gate structures 1430 to 1436. The cut patterns 1461 to 1463 can each be configured to form a dielectric structure, thereby dividing the gate structures 1430-1436 into separate gate sections. For example, the cut pattern 1461-1463 can divide the gate structures 1430, 1432, 1434, and 1436 into gate sections 1430A and 1430B, gate sections 1432A and 1432B, gate sections 1434A and 1434B, and gate sections 1436A and 1436B, respectively, as indicated in FIG. 14.

Referring next to FIG. 15, the layout 1500 can include patterns for forming active regions 1510 and 1520 and gate structures 1530, 1532, 1534 and 1536, respectively. The active regions 1510 and 1520 may extend in the X-direction; and the gate structures 1530 to 1536 may extend in the Y-direction. Each of the active regions 1510 and 1520 may be formed as a fin structure or a stack structure extending along the X-direction, and each of the gate structures 1530 to 1536 may be formed to extend in the Y-direction to traverse the active regions 1510 and 1520. The layout 1500 can further include a number of cut patterns, e.g., 1562, 1562, and 1563, each of which can extend along the X-direction traversing the gate structures 1530 to 1536. The cut patterns 1561 to 1563 can each be configured to form a dielectric structure, thereby dividing the gate structures 1530-1536 into separate gate sections. For example, the cut pattern 1561-1563 can divide the gate structures 1530, 1532, 1534, and 1536 into gate sections 1530A and 1530B, gate sections 1532A and 1532B, gate sections 1534A and 1534B, and gate sections 1536A and 1536B, respectively, as indicated in FIG. 15.

In some embodiments, the active regions 1410 and 1510 are vertically aligned with each other, the active regions 1420 and 1520 are vertically aligned with each other, the gate structures 1430 and 1530 are vertically aligned with each other, the gate structures 1432 and 1532 are vertically aligned with each other, the gate structures 1434 and 1534 are vertically aligned with each other, the gate structures 1436 and 1536 are vertically aligned with each other, the cut patterns 1461 and 1561 are vertically aligned with each other, the cut patterns 1462 and 1562 are vertically aligned with each other, and the cut patterns 1463 and 1563 are vertically aligned with each other. Further, the active regions 1410 and 1510 may be physically formed as a single structure (sometimes referred to as “active region 1410/1510”), the active regions 1420 and 1520 may be physically formed as a single structure (sometimes referred to as “active region 1420/1520”), the gate structures 1430 and 1530 may be physically formed as a single structure (sometimes referred to as “gate structure 1430/1530”), the gate structures 1432 and 1532 may be physically formed as a single structure (sometimes referred to as “gate structure 1432/1532”), the gate structures 1434 and 1534 may be physically formed as a single structure (sometimes referred to as “gate structure 1434/1534”), and the gate structures 1436 and 1536 may be physically formed as a single structure (sometimes referred to as “gate structure 1436/1536”).

Based on the manufacturing processes described below with respect to FIGS. 17-38, the layouts 1400 and 1500 can be collectively utilized to form a number of first transistors at a first level on the frontside of a substrate and a number of second transistor at a second, upper level on the frontside, in which the first transistors are operatively formed based on a plural number of first nanosheets and a plural number of first epitaxial structures, and the second transistors are operatively formed based on a plural number of second nanosheets and a plural number of second epitaxial structures.

For example, the transistors PU1, PU2, PG1, and PG2 of the first memory cell 100 and the transistors PU1, PU2, PG1, and PG2 of the second memory cell 100 can be formed at the first level based on the layout 1400 (as indicated in FIG. 14), and the transistors PD1 and PD2 of the first memory cell 100 and the transistors PD1 and PD2 of the second memory cell 100 can be formed at the second level based on the layout 1500 (as indicated in FIG. 15). Further, in some embodiments, the transistors PU1, PU2, PG1, and PG2 of the first and second memory cells 100 at the first level can be formed with the p-type conductivity, and the transistors PD1 and PD2 of the first and second memory cells 100 at the second level can be formed with the n-type conductivity.

As a representative example, in FIG. 14, the transistor PU1 of the first memory cell 100 can include its channel, gate terminal, and source/drain terminals formed by a subset of the first nanosheets in the active region 1410, the gate section 1432A, and a subset of the first epitaxial structures formed from the active region 1410 and disposed on opposite sides of the gate section 1432A, respectively. The transistor PG1 of the first memory cell 100 can include its channel, gate terminal, and source/drain terminals formed by another subset of the first nanosheets in the active region 1410, the gate section 1430A, and another subset of the first epitaxial structures formed from the active region 1410 and disposed on opposite sides of the gate section 1430A, respectively. The transistor PU2 of the first memory cell 100 can include its channel, gate terminal, and source/drain terminals formed by yet another subset of the first nanosheets in the active region 1410, the gate section 1434A, and yet another subset of the first epitaxial structures formed from the active region 1410 and disposed on opposite sides of the gate section 1434A, respectively. The transistor PG2 of the first memory cell 100 can include its channel, gate terminal, and source/drain terminals formed by yet another subset of the first nanosheets in the active region 1410, the gate section 1436A, and yet another subset of the first epitaxial structures formed from the active region 1410 and disposed on opposite sides of the gate section 1436A, respectively.

As another representative example, in FIG. 15, the transistor PD1 of the first memory cell 100 can include its channel, gate terminal, and source/drain terminals formed by a subset of the second nanosheets in the active region 1510, the gate section 1532A, and a subset of the second epitaxial structures formed from the active region 1510 and disposed on opposite sides of the section 1532A, respectively. The transistor PD2 of the first memory cell 100 can include its channel, gate terminal, and source/drain terminals formed by another subset of the second nanosheets in the active region 1510, the gate section 1534A, and another subset of the second epitaxial structures formed from the active region 1510 and disposed on opposite sides of the gate section 1534A, respectively. Further, a dummy transistor X1 of the first memory cell 100 can include its channel, gate terminal, and source/drain terminals formed by another subset of the second nanosheets in the active region 1510, the gate section 1530A, and another subset of the second epitaxial structures formed from the active region 1510 and disposed on opposite sides of the gate section 1530A, respectively. A dummy transistor X2 of the first memory cell 100 can include its channel, gate terminal, and source/drain terminals formed by a subset of the second nanosheets in the active region 1510, the gate section 1536A, and a subset of the second epitaxial structures formed from the active region 1510 and disposed on opposite sides of the gate section 1536A, respectively.

Referring again to FIG. 14, the layout 1400 can further include patterns for forming source/drain contact structures (MDs) 1440, 1442, 1444, 1446, 1448, 1450, 1452, 1454, and 1456, respectively. Similarly in FIG. 15, the layout 1500 can further include patterns for forming source/drain contact structures (MDs) 1540, 1542, 1544, 1546, 1548, 1550, 1552, 1554, and 1556, respectively. Each of these MDs is configured to electrically connect to the source/drain terminal of a corresponding transistor.

For example, in FIG. 14, the MD 1440 is connected to a first source/drain terminal of the transistor PG1 of the first memory cell 100; the MD 1442 is connected to a second source/drain terminal of the transistor PG1 and a first source/drain terminal of the transistor PU1 of the first memory cell 100; the MID 1444 is connected to a second source/drain terminal of the transistor PU1 and a first source/drain terminal of the transistor PU2 of the first memory cell 100; the MD 1446 is connected to a second source/drain terminal of the transistor PU2 and a first source/drain terminal of the transistor PG2 of the first memory cell 100; and the MD 1448 is connected to a second source/drain terminal of the transistor PG2 of the first memory cell 100. In some embodiments, the MD 1444 is shared by the first and second memory cells 100 (e.g., the commonly connected source/drain terminals of the transistors PU1 and PU2 of each of the first and second memory cells). In FIG. 15, the MD 1542 is connected to a first source/drain terminal of the transistor PD1 of the first memory cell 100; the MD 1544 is connected to a second source/drain terminal of the transistor PD1 and a first source/drain terminal of the transistor PD2 of the first memory cell 100; and the MD 1546 is connected to a second source/drain terminal of the transistor PD2 of the first memory cell 100. In some embodiments, the MD 1544 is shared by the first and second memory cells 100 (e.g., the commonly connected source/drain terminals of the transistors PD1 and PD2 of each of the first and second memory cells).

In some embodiments, for the first memory cell 100, the MD 1442 (FIG. 14) and MD 1542 (FIG. 15) may be connected to each other through a first internal via structure (not shown), and the MD 1446 (FIG. 14) and MD 1546 (FIG. 15) may be connected to teach other through a second internal via structure (not shown). Stated another way, the first internal via structure can vertically extend from the first level to the second level to connect the MD 1442 to the MD 1542, and the second internal via structure can vertically extend from the first level to the second level to connect the MD 1446 to the MD 1546. As such, the node 110 of the first memory cell 100, at which the respective source/drain terminals of the transistors PU1, PD1, and PG1 are connected to one another, can be operatively formed based on the MD 1442, the MD 1542, and the first internal via structure vertically interposed therebetween, and the node 112 of the first memory cell 100, at which the respective source/drain terminals of the transistors PU2, PD2, and PG2 are connected to one another, can be operatively formed based on the MD 1446, the MD 1546, and the second internal via structure vertically interposed therebetween. The connections among the MDs for the second memory cell 100 are the same, so that the description is not repeated.

Referring again to FIG. 14, the layout 1400 can further include patterns for forming a number of first via structures (BVDs) 1472, 1473, 1474, 1475, 1476, 1477, and 1478, respectively. In some embodiments, each of the BVDs 1472 to 1478 can be formed below an MD included in the layout 1400. Particularly, the BVDs 1472 to 1478 can each downwardly extend from the corresponding MD to a backside of the substrate. For example, the BVD 1472 can be coupled to and downwardly extend from the MD 1440; the BVD 1473 can be coupled to and downwardly extend from the MD 1442; the BVD 1474 can be coupled to and downwardly extend from the MD 1448; the BVD 1475 can be coupled to and downwardly extend from the MD 1450; the BVD 1476 can be coupled to and downwardly extend from the MD 1452; the BVD 1477 can be coupled to and downwardly extend from the MD 1456; and the BVD 1478 can be coupled to and downwardly extend from the MD 1444.

Further, in some embodiments, the BVD 1472 can electrically connect the MD 1440 to a first interconnect structure formed on the backside (e.g., a first BM0 track) and configured as a first portion of the BL of the first memory cell 100; the BVD 1478 can electrically connect the MD 1444 to a second interconnect structure formed on the backside (e.g., a second BM0 track) and configured to carry the supply voltage VDD for both of the first and second memory cells 100; the BVD 1474 can electrically connect the MD 1448 to a third interconnect structure formed on the backside (e.g., a third BM0 track) and configured as a first portion of the BLB of the first memory cell 100; the BVD 1475 can electrically connect the MD 1450 to a fourth interconnect structure formed on the backside (e.g., a fourth BM0 track) and configured as a first portion of the BL of the second memory cell 100; and the BVD 1477 can electrically connect the MD 1456 to a fifth interconnect structure formed on the backside (e.g., a fifth BM0 track) and configured as a first portion of the BLB of the second memory cell 100.

The layout 1400 can further include patterns for forming a number of second via structures (BVGs) 1480, 1481, 1482, 1483, 1484, and 1485, respectively. In some embodiments, each of the BVGs 1480 and 1485 can be formed below a gate structure in the layout 1400. Particularly, the BVGs 1480 and 1485 can each downwardly extend from the corresponding gate structure (or gate section). For example, the BVG 1480 can be coupled to and downwardly extend from the gate section 1430A; the BVG 1481 can be coupled to and downwardly extend from the gate section 1434A; the BVG 1482 can be coupled to and downwardly extend from the gate section 1436A; the BVG 1483 can be coupled to and downwardly extend from the gate section 1430B; the BVG 1484 can be coupled to and downwardly extend from the gate section 1434B; and the BVG 1485 can be coupled to and downwardly extend from the gate section 1436B. In some embodiments, the BVGs 1480 and 1482 can electrically connect the gate sections 1430A and 1436A (the respective gate terminals of the transistors PG1 and PG2 of the first memory cell 100) to the WL of the first memory cell 100; and BVGs 1483 and 1485 can electrically connect the gate sections 1430B and 1436B (the respective gate terminals of the transistors PG1 and PG2 of the second memory cell 100) to the WL of the second memory cell 100. The first and second memory cells may share one common WL.

The layout 1400 can further include patterns forming internal contact structures 1490 and 1492, respectively. The internal contact structures 1490 and 1492 can extend along the X-direction, and be formed on the backside of the substrate (e.g., as BM0 tracks). In some embodiments, the internal contact structures 1490 and 1492 can each be configured to electrically connect an internal node of the memory cell 100 to the gate terminal(s) of one or more transistors. For example, in the first memory cell 100, the internal contact structure 1490 can electrically connect the MD 1442 (the common source/drain terminals of the transistors PG1 and PU1, or the internal node 110) to the gate section 1434A (the gate terminal of the transistor PU2) through the BVD 1473 and the BVG 1481; and, in the second memory cell 100, the internal contact structure 1492 can electrically connect the MD 1452 (the common source/drain terminals of the transistors PG1 and PU1, or the internal node 110) to the gate section 1434B (the gate terminal of the transistor PU2) through the BVD 1476 and the BVG 1484.

Referring again to FIG. 15, the layout 1500 can further include patterns for forming a number of first via structures (VDs) 1572, 1573, 1574, 1575, 1576, 1577, and 1578, respectively. In some embodiments, each of the VDs 1572 to 1578 can be formed above an MD included in the layout 1500. Particularly, the VDs 1572 to 1578 can each upwardly extend from the corresponding MD. For example, the VD 1572 can be coupled to and upwardly extend from the MD 1540; the VD 1573 can be coupled to and upwardly extend from the MD 1546; the VD 1574 can be coupled to and upwardly extend from the MD 1548; the VD 1575 can be coupled to and upwardly extend from the MD 1550; the VD 1576 can be coupled to and upwardly extend from the MD 1554; the VD 1577 can be coupled to and upwardly extend from the MD 1556; and the VD 1578 can be coupled to and upwardly extend from the MD 1544. In some embodiments, the VD 1570 allows the MD 1544 (the commonly connected source/drain terminals of the transistors PD1 and PD2 of each of the first and second memory cells 100) to one or more interconnect structures formed in an upper level (e.g., a first interconnect structure formed at a third, upper level on the frontside and configured to carry the ground voltage VSS). The layout 1500 can further include patterns for forming a number of second via structures (VGs) 1580 and 1582, respectively. In some embodiments, each of the VGs 1580 and 1582 can be formed above a gate section in the layout 1500. Particularly, the VGs 1580 and 1582 can upwardly extend from the corresponding gate section.

The layout 1500 can further include patterns for forming internal contact structures 1590 and 1592, respectively. The internal contact structures 1590 and 1592 can extend along the X-direction, and be formed on third, upper level on the frontside (e.g., as M0 tracks). In some embodiments, the internal contact structures 1590 and 1592 can each be configured to electrically connect an internal node of the memory cell 100 to the gate terminal(s) of one or more transistors. For example, in the first memory cell 100, the internal contact structure 1590 can electrically connect the MD 1546 (one of the source/drain terminals of the transistors PD2, or the internal node 112) to the gate section 1532A (the gate terminal of the transistor PD1) through the VD 1573 and the VG 1580; and, in the second memory cell 100, the internal contact structure 1592 can electrically connect the MD 1554 (one of the source/drain terminals of the transistors PD2, or the internal node 112) to the gate section 1532B (the gate terminal of the transistor PD1) through the VD 1576 and the VG 1582.

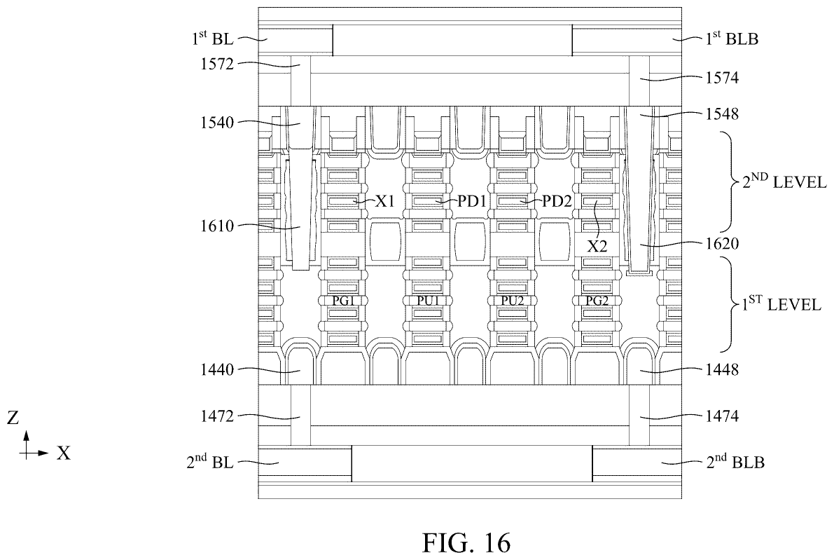

FIG. 16 illustrates a cross-sectional views of a portion of a semiconductor device formed based on the layouts 1400 and 1500 (FIGS. 14-15), in accordance with some embodiments. For example, the cross-sectional views of FIG. 16 is cut along line A-A indicated in FIGS. 14-15. The cross-sectional views of FIG. 16 is substantially similar to the cross-sectional view shown in FIG. 6, and thus, the following description will be focused on the difference.

As shown, the transistors PG1, PU1, PU2, and PG2 of the first memory cell 100 are formed at the first level, and the transistors PD1, PD2, X1, and X2 of the first memory cell 100 are formed at the second level. Each of the transistors PG1, PG2, PD1, PD2, PU1, and PU2 includes a number of nanostructures (collectively serving as its channel), a gate structure wrapping around each of the nanostructures, and a pair of epitaxial structures coupled to ends of each of the nanostructures, as described above. Further, the epitaxial structures of the transistors PG1, PU1, PU2, and PG2 have the p-type conductivity, and the epitaxial structures of the transistors PD1 and PD2 have the n-type conductivity.

In FIG. 16, one of the source/drain terminals of the transistor X1 can be partially replaced by a first vertical contact structure 1610, and one of the source/drain terminals of the transistor X2 can be partially replaced by a second vertical contact structure 1620. As shown, the vertical contact structure 1610 can extends through the second level. Further, the vertical contact structure 1610 can electrically connect the first portion of the BL (or the first BL) to the second portion of the BL (of the second BL) through the VD 1572, MD 1540, one of the source/drain terminal of the transistor PG1, MD 1440, and BVD 1472. Similarly, the vertical contact structure 1620 can electrically connect the first portion of the BLB (or the first BLB) to the second portion of the BLB (of the second BLB) through the VD 1574, MD 1548, one of the source/drain terminal of the transistor PG2, MD 1448, and BVD 1474.

FIG. 17 illustrates a flow chart of an example method 1700 for forming a memory cell configured in a CFET structure, according to some embodiments of the present disclosure. For example, at least some of the operations (or steps) of the method 1700 can be used to form the memory cell 100 (FIG. 1) or the memory cell 700 (FIG. 7) in the CFET structure, which includes a number of p-type transistors disposed at the first level on the frontside of a substrate and a number of n-type transistors disposed at the second, upper level on the frontside of the substrate.

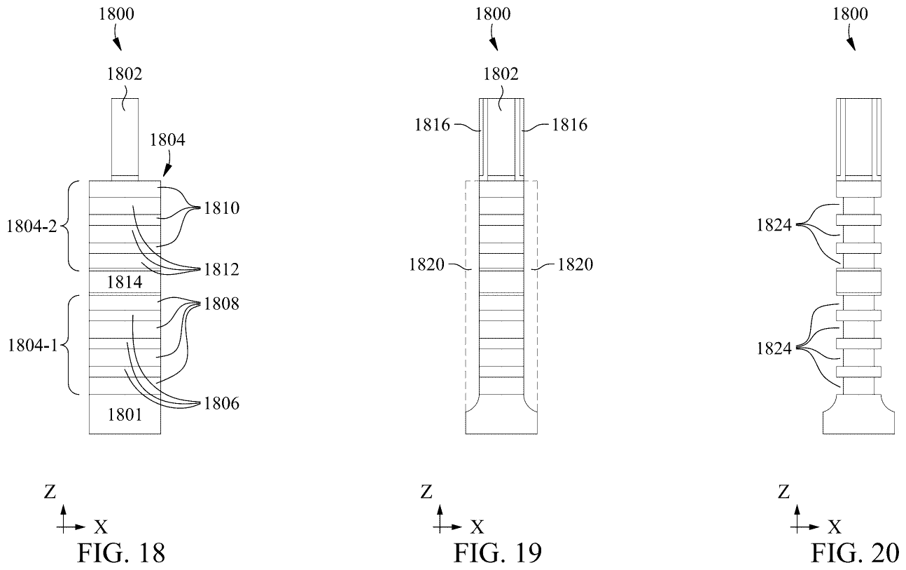

It should be appreciated that the method 1700 is merely an example, and is not intended to limit the present disclosure. Accordingly, it is understood that additional operations may be provided before, during, and after the method 1700 of FIG. 17, and that some other operations may only be briefly described herein. In some embodiments, operations of the method 1700 may be associated with cross-sectional views of a CFET structure 1800 at various fabrication stages as shown in FIGS. 18, 19, 20, 21, 22, 23, 24, 25, and 26, respectively, which will be discussed in further detail below.

As a brief overview, the method 1700 starts with operation 1702 of forming a number of dummy gate structures over a stack including a lower portion and an upper portion. The lower portion includes a number of first nanostructures and a number of second nanostructures alternately stacked on top of one another, and the upper portion includes a number of third nanostructures and a number of fourth nanostructures alternately stacked on top of one another. The first and third nanostructures may be formed of a first semiconductor material, and the second and fourth nanostructures may be formed of a second semiconductor material. Further, the lower portion and the upper portion may be separated from each other with a fifth nanostructure formed of a third semiconductor material. The method 1700 continues to operation 1704 of etching the stack to form source/drain recesses. The 1700 continues to operation 1706 of laterally recessing the second nanostructures and the fourth nanostructures. The method 1700 continues to operation 1708 of forming a number of inner spacers. The method 1700 continues to operation 1710 of selectively removing the fifth nanostructure. The method 1700 continues to operation 1712 of forming a dielectric layer between the lower portion and the upper portion. The method 1700 continues to operation 1714 of forming a number of p-type epitaxial structures in the lower portion and a number of n-type epitaxial structures in the upper portion. The method 1700 continues to operation 1716 of forming a first active gate structure in the lower portion and a second active gate structure in the upper portion. The method 1700 continues to operation 1718 of forming a number of connection structures.

Corresponding to operation 1702 of FIG. 17, FIG. 18 is a cross-sectional view of the CFET structure 1800 including a number of dummy gate structures 1802 over a stack 1804, at one of the various stages of fabrication. The cross-sectional view of FIG. 18 is cut along the lengthwise direction of an active region of the CFET structure 1800 (e.g., the X-direction illustrated above).

In some embodiments, the stack 1804 may be formed over a semiconductor substrate 1801, followed by the dummy gate structure 1802 formed over the stack 1804. The stack 1804 can extend along the X-direction, and the dummy gate structure 1802 can extend along the Y-direction to straddle or otherwise traverse the stack 1804. The stack 1804 includes a lower portion 1804-1 and an upper portion 1804-2, which can correspond to the first level and the second level on the frontside of the substrate, respectively. The lower portion 1804-1 includes a number of first nanostructures 1806 and a number of second nanostructures 1808 alternately stacked on top of one another, and the upper portion 1804-2 includes a number of third nanostructures 1810 and a number of fourth nanostructures 1812 alternately stacked on top of one another.

The substrate 1801, the first nanostructures 1806, and the third nanostructures 1810 may be formed of a first semiconductor material, e.g., silicon (Si), while the second nanostructures 1808 and the fourth nanostructures 1812 may be formed of a second semiconductor material, e.g., silicon germanium (Si₁₋ₓGeₓ). Further, the lower portion 1804-1 and the upper portion 1804-2 are separated from each other with a fifth nanostructure 1814 formed of a third semiconductor material, e.g., silicon germanium (Si_{1-y}Ge_{y}). In some embodiments, the molar ratio “x” of the second semiconductor material may be less than 0.5, and the molar ratio “y” of the third semiconductor material may be higher than 0.5.

The nanostructures 1806 to 18172 can be epitaxially grown from the semiconductor substrate 1801. For example, each of the nanostructures 1806 to 18172 may be grown by a molecular beam epitaxy (MBE) process, a chemical vapor deposition (CVD) process such as a metal organic CVD (MOCVD) process, and/or other suitable epitaxial growth processes. Upon growing the nanostructures 1806 to 18172 on the substrate 1801 as a blanket stack, the blanket stack may be patterned to form the stack 1804 shown in FIG. 18 (e.g., having a lengthwise direction in the X-direction and a relatively narrow width in the Y-direction). After the stack 1804 is formed, the dummy gate structure 1802, including a dummy gate dielectric (e.g., silicon oxide) and a dummy gate material (e.g., polysilicon), is formed to straddle the stack 1804.

Corresponding to operation 1704 of FIG. 17, FIG. 19 is a cross-sectional view of the CFET structure 1800 in which source/drain recesses 1820 are formed, at one of the various stages of fabrication. The cross-sectional view of FIG. 19 is cut along the lengthwise direction of an active region of the CFET structure 1800 (e.g., the X-direction illustrated above).

To form the source/drain recesses 1820, a pair of gate spacers 1816 may be formed on opposite sidewalls of the dummy gate structure 1802. Next, with the dummy gate structure 1802 and the gate spacers 1816 serving as a mask, the stack 1804 is again patterned to form the source/drain recesses 1820 using an anisotropic etching process. Such an anisotropic etching process can include reactive ion etch (RIE), neutral beam etch (NBE), the like, or combinations thereof.

Corresponding to operation 1706 of FIG. 17, FIG. 20 is a cross-sectional view of the CFET structure 1800 in which the second nanostructures 1808 and the fourth nanostructures 1812 are laterally recessed, at one of the various stages of fabrication. The cross-sectional view of FIG. 20 is cut along the lengthwise direction of an active region of the CFET structure 1800 (e.g., the X-direction illustrated above).

As shown, respective end portions of each of the second nanostructures 1808 and the fourth nanostructures 1812 (formed of Si₁₋ₓGeₓ) are removed (e.g., etched) using a “pull-back” process to pull each of the nanostructures 1808 and 18172 back by a pull-back distance. For example, the pull-back process may include a hydrogen chloride (HCl) gas isotropic etching process, which etches SiGe with the lower Ge composition (e.g., Si₁₋ₓGeₓ) without attacking Si or SiGe with the higher Ge composition (e.g., Si_{1-y}Ge_{y}). As such, the nanostructures 1806 (Si), 18170 (Si), and 18174 (Si₁₋Ge_{y}) may remain substantially intact during this process, and a number of recess 1824, each inwardly extending from the source/drain recess 1820, can be formed.

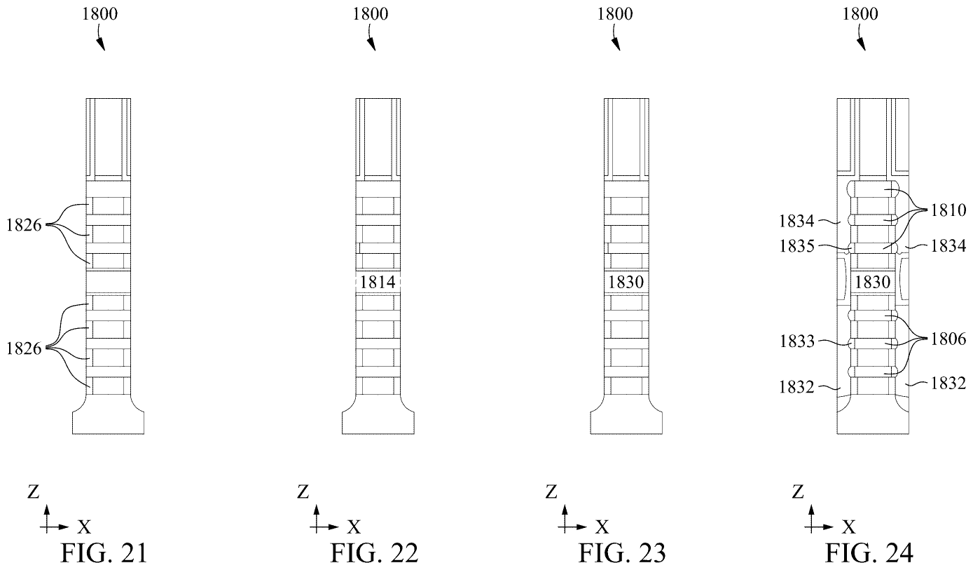

Corresponding to operation 1708 of FIG. 17, FIG. 21 is a cross-sectional view of the CFET structure 1800 including a number of inner spacers 1826, at one of the various stages of fabrication. The cross-sectional view of FIG. 21 is cut along the lengthwise direction of an active region of the CFET structure 1800 (e.g., the X-direction illustrated above).

The inner spacers 1826 can be formed by filling the recesses 1824 with a dielectric material. For example, the inner spacers 1826 can be deposited using, e.g., a conformal deposition process and subsequent isotropic or anisotropic etch back to remove excess spacer material on the sidewalls of the stack 1804. The dielectric material, used to form the inner spacer 1818, includes silicon nitride, silicoboron carbonitride, silicon carbonitride, silicon carbon oxynitride, or any other type of dielectric material (e.g., a dielectric material having a dielectric constant k of less than about 5) appropriate to the role of forming an insulating gate sidewall spacers of transistors.

Corresponding to operation 1710 of FIG. 17, FIG. 22 is a cross-sectional view of the CFET structure 1800 in which the fifth nanostructure 1814 is removed, at one of the various stages of fabrication. The cross-sectional view of FIG. 22 is cut along the lengthwise direction of an active region of the CFET structure 1800 (e.g., the X-direction illustrated above).

After forming the inner spacers 1826, the fifth nanostructure 1814 can be selectively removed using an isotropic etching process that etches Si_{1-y}Ge_{y} without attacking Si. As such, the first nanostructures 1806 (Si) and third nanostructures 1810 (Si) can remain substantially intact, the fifth nanostructure 1814 (Si_{1-y}Ge_{y}) can be completely removed, and the remaining portions of the second nanostructures 1808 (Si₁₋ₓGeₓ) and fourth nanostructures 1812 (Si₁₋ₓGeₓ) can remain with the protection of the inner spacers 1826.

Corresponding to operation 1712 of FIG. 17, FIG. 23 is a cross-sectional view of the CFET structure 1800 including a dielectric layer 1830, at one of the various stages of fabrication. The cross-sectional view of FIG. 23 is cut along the lengthwise direction of an active region of the CFET structure 1800 (e.g., the X-direction illustrated above).

After the fifth nanostructure 1814 is removed, a space is formed between the lower portion 1804-1 and the upper portion 1804-2. The dielectric layer 1830 can be formed by filling the space with a dielectric material. The dielectric material, used to form the dielectric layer 1830, includes silicon nitride, silicoboron carbonitride, silicon carbonitride, silicon carbon oxynitride, or any other type of dielectric material (e.g., a dielectric material having a dielectric constant k of less than about 5) appropriate to the role of forming an insulating structure for transistors.

Corresponding to operation 1714 of FIG. 17, FIG. 24 is a cross-sectional view of the CFET structure 1800 including a number of first epitaxial structures 1832 and a number of second epitaxial structures 1834, at one of the various stages of fabrication. The cross-sectional view of FIG. 24 is cut along the lengthwise direction of an active region of the CFET structure 1800 (e.g., the X-direction illustrated above).

As shown, a pair of the first epitaxial structure 1832 are coupled to ends of each of the first nanostructures 1806, respectively; and a pair of the second epitaxial structure 1834 are coupled to ends of each of the third nanostructures 1810, respectively. The first epitaxial structures 1832 can be formed through a first epitaxial growth process, followed by a second epitaxial growth process for forming the second epitaxial structures 1834. Further, between the first epitaxial growth process and the second epitaxial growth process, one or more dielectric layers 1836 can be formed to electrically isolate the first epitaxial structures 1832 and the second epitaxial structures 1834. Each of the first epitaxial growth process and the second epitaxial growth process can include a selective epitaxial growth (SEG) process, CVD deposition techniques (e.g., vapor-phase epitaxy (VPE) and/or ultra-high vacuum CVD (UHV-CVD)), molecular beam epitaxy, or other suitable epitaxial processes. Specifically, the first epitaxial structures 1832 can be grown from the first nanostructures 1806, and the second epitaxial structures 1834 can be grown from the third nanostructures 1810.

The first epitaxial structures 1832 and the second epitaxial structures 1834 may each include silicon germanium (SiGe), indium arsenide (InAs), indium gallium arsenide (InGaAs), indium antimonide (InSb), germanium arsenide (GaAs), germanium antimonide (GaSb), indium aluminum phosphide (InAlP), indium phosphide (InP), any other suitable material, or combinations thereof. Further, in-situ doping (ISD) may be applied during the formation of each of the first epitaxial structures 1832 and the second epitaxial structures 1834. For example, the first epitaxial structures 1832 can be doped by implanting p-type dopants, e.g., boron (B), etc., into them; and the second epitaxial structures 1834 can be doped by implanting n-type dopants, e.g., arsenic (As), phosphorous (P), etc., into them. In some embodiments, the first epitaxial structure 1832 can be coupled to each of the first nanostructures 1806 through a lightly doped region 1833 (e.g., SiGeB); and the second epitaxial structure 1834 can be coupled to each of the third nanostructures 1810 through a lightly doped region 1835 (e.g., SiP).

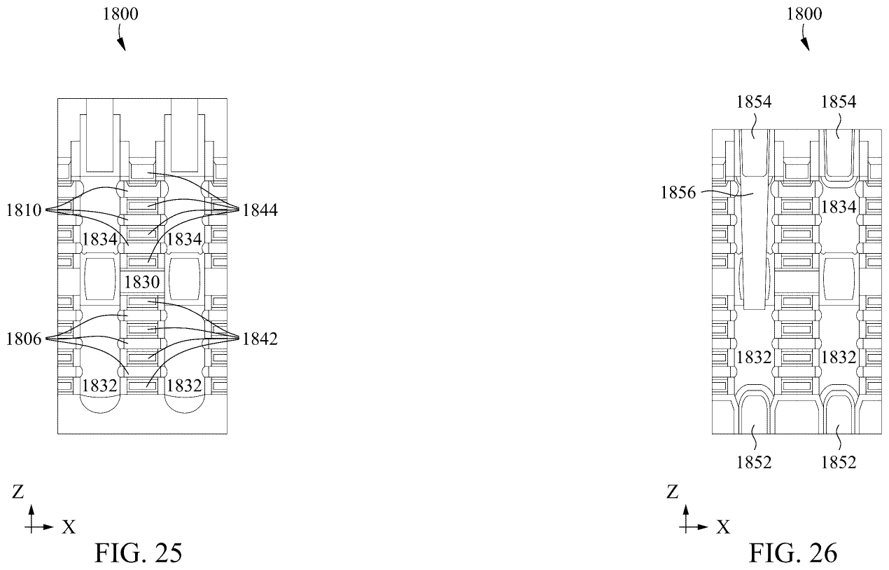

Corresponding to operation 1716 of FIG. 17, FIG. 25 is a cross-sectional view of the CFET structure 1800 including a first active gate structure 1842 and a second active gate structure 1844, at one of the various stages of fabrication. The cross-sectional view of FIG. 25 is cut along the lengthwise direction of an active region of the CFET structure 1800 (e.g., the X-direction illustrated above).

As shown, the first active gate structure 1842 wraps around each of the first nanostructures 1806; and the second active gate structure 1844 wraps around each of the third nanostructures 1810. To form the first active gate structure 1842 and second active gate structure 1844, the dummy gate structure 1802, the remaining portions of the second nanostructures 1808, and the remaining portions of the fourth nanostructures 1812 are removed. As such, a first gate trench, exposing each of the first nanostructures 1806, may be formed in the lower portion 1804-1 (e.g., the first level); and a second gate trench, exposing each of the third nanostructures 1810, may be formed in the upper portion 1804-2 (e.g., the second level). Next, the first active gate structure 1842 can be formed in the first gate trench to wrap around each of the first nanostructures 1806; and the second active gate structure 1844 can be formed in the second gate trench to wrap around each of the third nanostructures 1810.

In some embodiments, the first active gate structure 1842 can include a first gate dielectric and a first gate metal; and the second active gate structure 1844 can include a second gate dielectric and a second gate metal. The first/second gate dielectric may be formed of different high-k dielectric materials or a similar high-k dielectric material. Example high-k dielectric materials include a metal oxide or a silicate of Hf, Al, Zr, La, Mg, Ba, Ti, Pb, and combinations thereof. The first/second gate dielectric may include a stack of multiple high-k dielectric materials. The first gate metal may include one or more p-type work function metals, which may include TiN, TaN, Ru, Mo, Al, WN, ZrSi₂, MoSi₂, TaSi₂, NiSi₂, WN, other suitable p-type work function materials, or combinations thereof; and the second gate metal may include one or more n-type work function metals, may include Ti, Ag, TaAl, TaAlC, TiAlN, TaC, TaCN, TaSiN, Mn, Zr, other suitable n-type work function materials, or combinations thereof.

Upon the first and second active gate structures 1842-1844 being formed, at least one p-type transistor can be formed at the first level, and at least one n-type transistor can be formed at the second level. The p-type transistor can be operatively formed based on the first nanostructures 1806, the gate structure 1842, and the pair of first epitaxial structures 1832, which can, for example, correspond to the nanostructures 610, gate structure 612, and epitaxial structures 614 (FIG. 6), respectively. The n-type transistor can be operatively formed based on the third nanostructures 1810, the gate structure 1844, and the pair of second epitaxial structures 1834, which can, for example, correspond to the nanostructures 620, gate structure 622, and epitaxial structures 624 (FIG. 6), respectively.

Corresponding to operation 1718 of FIG. 17, FIG. 26 is a cross-sectional view of the CFET structure 1800 including a first connection structure 1852, a second connection structure 1854, and a third connection structure 1856, at one of the various stages of fabrication. The cross-sectional view of FIG. 26 is cut along the lengthwise direction of an active region of the CFET structure 1800 (e.g., the X-direction illustrated above).

As shown, the first connection structure 1852 is coupled to a corresponding one of the first epitaxial structures 1832; and the second connection structure 1854 is coupled to a corresponding one of the second epitaxial structures 1834. For example, the first connection structure 1852 may be formed below the first epitaxial structure 1832; and the second connection structure 1854 may be formed above the second epitaxial structure 1834. In some embodiments, the first connection structure 1852 and the second connection structure 1854 may each be configured as MD, as described above, which can include titanium, aluminum, nickel, tungsten, tantalum, or other suitable metal materials. The third connection structure 1856 may correspond to the above-described vertical contact structure (e.g., 660, 1610, 1620) that extends through the second frontside level to allow electrical connection between a first BL and a second BL disposed on the frontside and the backside of the substrate, respectively.

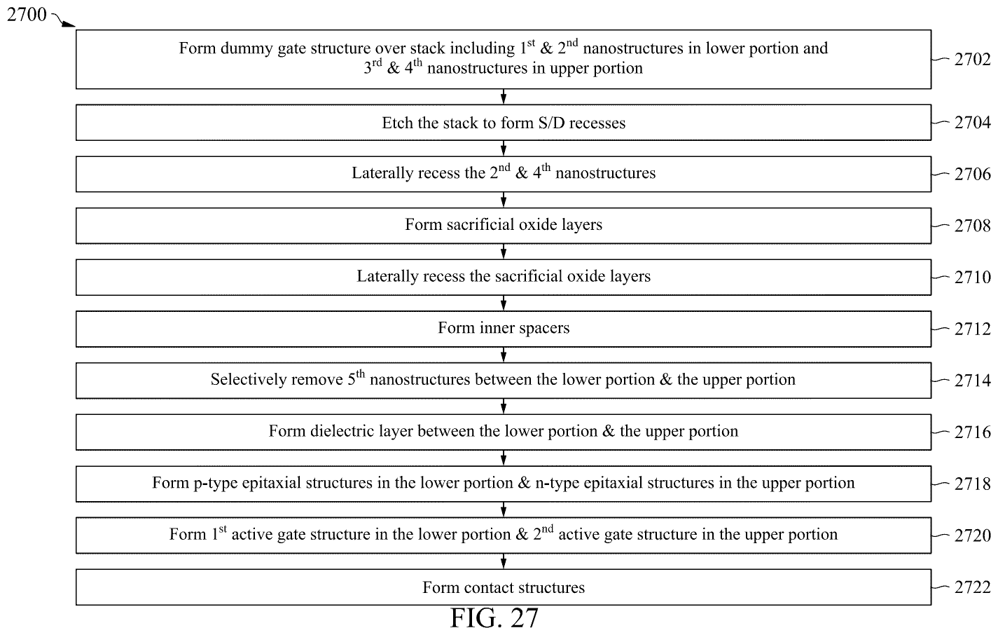

FIG. 27 illustrates a flow chart of another example method 2700 for forming a memory cell configured in a CFET structure, according to some embodiments of the present disclosure. For example, at least some of the operations (or steps) of the method 2700 can be used to form the memory cell 100 (FIG. 1) or the memory cell 700 (FIG. 7) in the CFET structure, which includes a number of p-type transistors disposed at the first level on the frontside of a substrate and a number of n-type transistors disposed at the second, upper level on the frontside of the substrate.

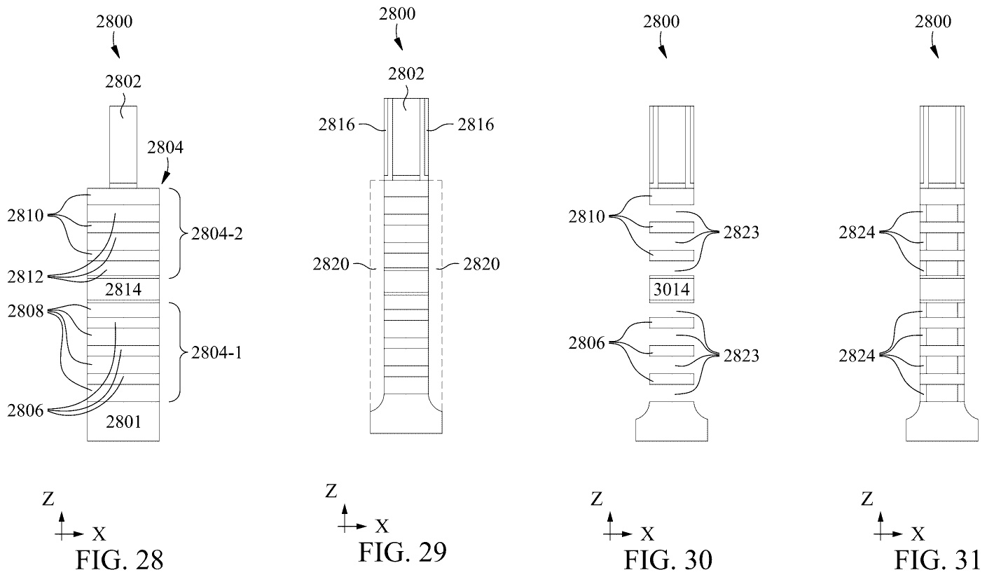

It should be appreciated that the method 2700 is merely an example, and is not intended to limit the present disclosure. Accordingly, it is understood that additional operations may be provided before, during, and after the method 2700 of FIG. 27, and that some other operations may only be briefly described herein. In some embodiments, operations of the method 2700 may be associated with cross-sectional views of a CFET structure 2800 at various fabrication stages as shown in FIGS. 28, 29, 30, 31, 32, 33, 34, 35, 36, 37, and 38, respectively, which will be discussed in further detail below.

As a brief overview, the method 2700 starts with operation 2702 of forming a number of dummy gate structures over a stack including a lower portion and an upper portion. The lower portion includes a number of first nanostructures and a number of second nanostructures alternately stacked on top of one another, and the upper portion includes a number of third nanostructures and a number of fourth nanostructures alternately stacked on top of one another. The first and third nanostructures may be formed of a first semiconductor material, and the second and fourth nanostructures may be formed of a second semiconductor material. Further, the lower portion and the upper portion may be separated from each other with a fifth nanostructure formed of a third semiconductor material. The method 2700 continues to operation 2704 of etching the stack to form source/drain recesses. The 2700 continues to operation 2706 of removing the second nanostructures and the fourth nanostructures. The method 2700 continues to operation 2708 of forming a plural number of sacrificial oxide layers each interposed between adjacent ones of the first nanostructures or between adjacent ones of the third nanostructures. The method 2700 continues to operation 2710 of laterally recessing the sacrificial oxide layers. The method 2700 continues to operation 2712 of forming a number of inner spacers. The method 2700 continues to operation 2714 of selectively removing the fifth nanostructure. The method 2700 continues to operation 2716 of forming a dielectric layer between the lower portion and the upper portion. The method 2700 continues to operation 2718 of forming a number of p-type epitaxial structures in the lower portion and a number of n-type epitaxial structures in the upper portion. The method 2700 continues to operation 2720 of forming a first active gate structure in the lower portion and a second active gate structure in the upper portion. The method 2700 continues to operation 2718 of forming a number of connection structures.

Corresponding to operation 2702 of FIG. 27, FIG. 28 is a cross-sectional view of the CFET structure 2800 including a number of dummy gate structures 2802 over a stack 2804, at one of the various stages of fabrication. The cross-sectional view of FIG. 28 is cut along the lengthwise direction of an active region of the CFET structure 2800 (e.g., the X-direction illustrated above).

In some embodiments, the stack 2804 may be formed over a semiconductor substrate 2801, followed by the dummy gate structure 2802 formed over the stack 2804. The stack 2804 can extend along the X-direction, and the dummy gate structure 2802 can extend along the Y-direction to straddle or otherwise traverse the stack 2804. The stack 2804 includes a lower portion 2804-1 and an upper portion 2804-2, which can correspond to the first level and the second level on the frontside of the substrate (e.g., FIGS. 10, 14, 24), respectively. The lower portion 2804-1 includes a number of first nanostructures 2806 and a number of second nanostructures 2808 alternately stacked on top of one another, and the upper portion 2804-2 includes a number of third nanostructures 2810 and a number of fourth nanostructures 2812 alternately stacked on top of one another.

The substrate 2801, the first nanostructures 2806, and the third nanostructures 2810 may be formed of a first semiconductor material, e.g., silicon (Si), while the second nanostructures 2808 and the fourth nanostructures 2812 may be formed of a second semiconductor material, e.g., silicon germanium (Si₁₋ₓGeₓ). Further, the lower portion 2804-1 and the upper portion 2804-2 are separated from each other with a fifth nanostructure 2814 formed of a third semiconductor material, e.g., silicon germanium (Si_{1-y}Ge_{y}). In some embodiments, the molar ratio “x” of the second semiconductor material may be less than 0.5, and the molar ratio “y” of the third semiconductor material may be higher than 0.5.

The nanostructures 2806 to 2772 can be epitaxially grown from the semiconductor substrate 2801. For example, each of the nanostructures 2806 to 2772 may be grown by a molecular beam epitaxy (MBE) process, a chemical vapor deposition (CVD) process such as a metal organic CVD (MOCVD) process, and/or other suitable epitaxial growth processes. Upon growing the nanostructures 2806 to 2772 on the substrate 2801 as a blanket stack, the blanket stack may be patterned to form the stack 2804 shown in FIG. 28 (e.g., having a lengthwise direction in the X-direction and a relatively narrow width in the Y-direction). After the stack 2804 is formed, the dummy gate structure 2802, including a dummy gate dielectric (e.g., silicon oxide) and a dummy gate material (e.g., polysilicon), is formed to straddle the stack 2804.

Corresponding to operation 2704 of FIG. 27, FIG. 29 is a cross-sectional view of the CFET structure 2800 in which source/drain recesses 2820 are formed, at one of the various stages of fabrication. The cross-sectional view of FIG. 29 is cut along the lengthwise direction of an active region of the CFET structure 2800 (e.g., the X-direction illustrated above).

To form the source/drain recesses 2820, a pair of gate spacers 2816 may be formed on opposite sidewalls of the dummy gate structure 2802. Next, with the dummy gate structure 2802 and the gate spacers 2816 serving as a mask, the stack 2804 is again patterned to form the source/drain recesses 2820 using an anisotropic etching process. Such an anisotropic etching process can include reactive ion etch (RIE), neutral beam etch (NBE), the like, or combinations thereof.

Corresponding to operation 2706 of FIG. 27, FIG. 30 is a cross-sectional view of the CFET structure 2800 in which the second nanostructures 2808 and the fourth nanostructures 2812 are removed, at one of the various stages of fabrication. The cross-sectional view of FIG. 30 is cut along the lengthwise direction of an active region of the CFET structure 2800 (e.g., the X-direction illustrated above).

In some embodiments, the second nanostructures 2808 and the fourth nanostructures 2812 may be selectively removed (e.g. etched), with the first nanostructures 2806, the third nanostructures 2810, and the fifth nanostructure 2814 remaining substantially intact. The second nanostructures 2808 and the fourth nanostructures 2812 may be completely removed using a hydrogen chloride (HCl) gas isotropic etching process, which etches SiGe with the lower Ge composition (e.g., Si₁₋ₓGeₓ) without attacking Si or SiGe with the higher Ge composition (e.g., Si_{1-y}Ge_{y}). As such, a plural number of spaces 2823 can be formed. Each of the spaces 2823 can be vertically interposed between the substrate 2801 and a bottommost one of the first nanostructures 2806, between the adjacent ones of the first nanostructures 2806, between a topmost one of the first nanostructures 2806 and the fifth nanostructure 2814, between the fifth nanostructure 2814 and a bottommost one of the third nanostructures 2810, or between the adjacent ones of the third nanostructures 2810, as shown in FIG. 30.

Corresponding to operation 2708 of FIG. 27, FIG. 31 is a cross-sectional view of the CFET structure 2800 including a plural number of sacrificial oxide layers 2824, at one of the various stages of fabrication. The cross-sectional view of FIG. 31 is cut along the lengthwise direction of an active region of the CFET structure 2800 (e.g., the X-direction illustrated above).

As shown, the sacrificial oxide layers 2824 are formed at least in the spaces 2823, respectively. In some embodiments, the sacrificial oxide layers 2824 may be formed using, e.g., a conformal deposition process to deposit an oxide material and one or more subsequent isotropic or anisotropic etching processes to remove the excessive oxide material on the sidewalls of the stack 2804. As such, the sacrificial oxide layers 2824 can each be vertically interposed between the substrate 2801 and the bottommost first nanostructures 2806, between the adjacent first nanostructures 2806, between the topmost first nanostructure 2806 and the fifth nanostructure 2814, between the fifth nanostructure 2814 and the bottommost third nanostructure 2810, or between the adjacent third nanostructures 2810, as shown in FIG. 31.

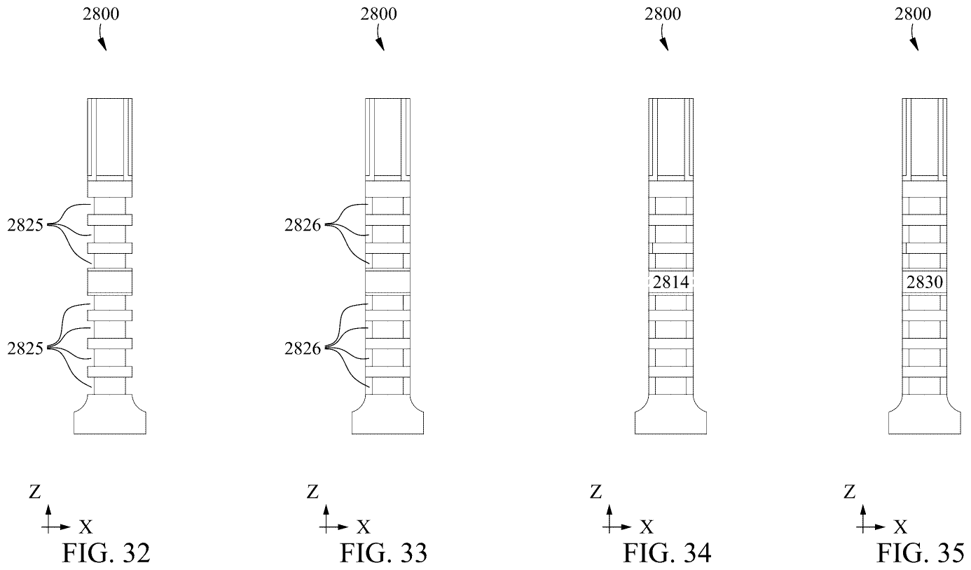

Corresponding to operation 2710 of FIG. 27, FIG. 32 is a cross-sectional view of the CFET structure 2800 in which the sacrificial oxide layers 2824 are laterally recessed, at one of the various stages of fabrication. The cross-sectional view of FIG. 32 is cut along the lengthwise direction of an active region of the CFET structure 2800 (e.g., the X-direction illustrated above).

As shown, respective end portions of each of the sacrificial oxide layers 2824 are removed (e.g., etched) using a “pull-back” process to pull each of the sacrificial oxide layers 2824 back by a pull-back distance. For example, the pull-back process may include a hydrofluoric acid (HF) gas isotropic etching process, which etches silicon oxide without attacking Si or SiGe with the higher Ge composition (e.g., Si_{1-y}Ge_{y}). As such, the nanostructures 2806 (Si), 2770 (Si), and 2774 (Si_{1-y}Ge_{y}) may remain substantially intact during this process, and a number of recesses 2825, each inwardly extending from the source/drain recess 2780, can be formed.

Corresponding to operation 2712 of FIG. 27, FIG. 33 is a cross-sectional view of the CFET structure 2800 including a number of inner spacers 2826, at one of the various stages of fabrication. The cross-sectional view of FIG. 33 is cut along the lengthwise direction of an active region of the CFET structure 2800 (e.g., the X-direction illustrated above).

The inner spacers 2826 can be formed by filling the recesses 2825 with a dielectric material. For example, the inner spacers 2826 can be deposited using, e.g., a conformal deposition process and subsequent isotropic or anisotropic etch back to remove excess spacer material on the sidewalls of the stack 2804. The dielectric material, used to form the inner spacer 2782, includes silicon nitride, silicoboron carbonitride, silicon carbonitride, silicon carbon oxynitride, or any other type of dielectric material (e.g., a dielectric material having a dielectric constant k of less than about 5) appropriate to the role of forming an insulating gate sidewall spacers of transistors.

Corresponding to operation 2714 of FIG. 27, FIG. 34 is a cross-sectional view of the CFET structure 2800 in which the fifth nanostructure 2814 is removed, at one of the various stages of fabrication. The cross-sectional view of FIG. 34 is cut along the lengthwise direction of an active region of the CFET structure 2800 (e.g., the X-direction illustrated above).

After forming the inner spacers 2826, the fifth nanostructure 2814 can be selectively removed using an isotropic etching process that etches Si_{1-y}Ge_{y} without attacking Si. As such, the first nanostructures 2806 (Si) and third nanostructures 2810 (Si) can remain substantially intact, the fifth nanostructure 2814 (Si_{1-y}Ge_{y}) can be completely removed, and the remaining portions of the sacrificial oxide layers 2824 can remain with the protection of the inner spacers 2826.

Corresponding to operation 2716 of FIG. 27, FIG. 35 is a cross-sectional view of the CFET structure 2800 including a dielectric layer 2830, at one of the various stages of fabrication. The cross-sectional view of FIG. 35 is cut along the lengthwise direction of an active region of the CFET structure 2800 (e.g., the X-direction illustrated above).

After the fifth nanostructure 2814 is removed, a space is formed between the lower portion 2804-1 and the upper portion 2804-2. The dielectric layer 2830 can be formed by filling the space with a dielectric material. The dielectric material, used to form the dielectric layer 2830, includes silicon nitride, silicoboron carbonitride, silicon carbonitride, silicon carbon oxynitride, or any other type of dielectric material (e.g., a dielectric material having a dielectric constant k of less than about 5) appropriate to the role of forming an insulating structure for transistors.

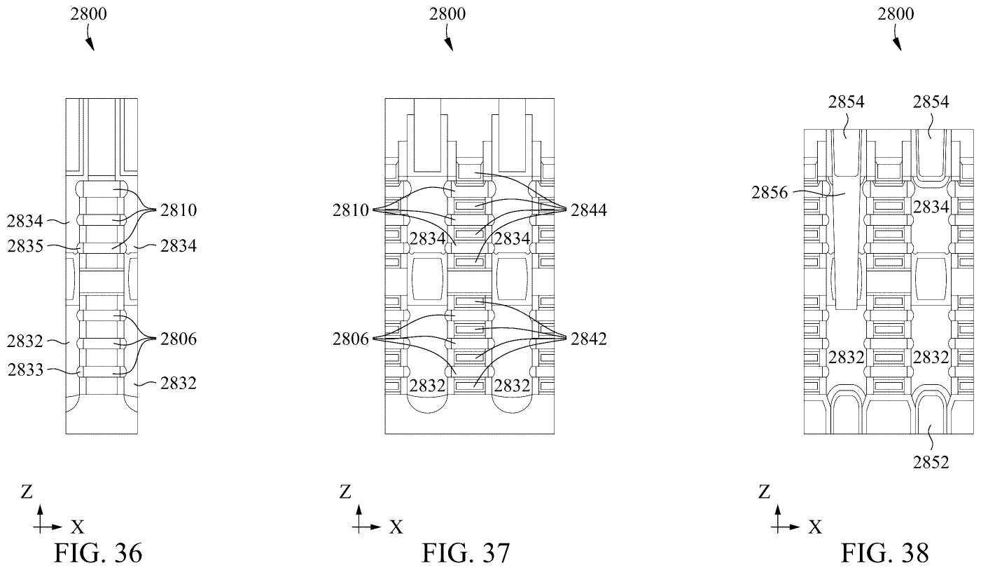

Corresponding to operation 2718 of FIG. 27, FIG. 36 is a cross-sectional view of the CFET structure 2800 including a number of first epitaxial structures 2832 and a number of second epitaxial structures 2834, at one of the various stages of fabrication. The cross-sectional view of FIG. 36 is cut along the lengthwise direction of an active region of the CFET structure 2800 (e.g., the X-direction illustrated above).

As shown, a pair of the first epitaxial structure 2828 are coupled to ends of each of the first nanostructures 2806, respectively; and a pair of the second epitaxial structure 2834 are coupled to ends of each of the third nanostructures 2810, respectively. The first epitaxial structures 2832 can be formed through a first epitaxial growth process, followed by a second epitaxial growth process for forming the second epitaxial structures 2834. Further, between the first epitaxial growth process and the second epitaxial growth process, one or more dielectric layers 2836 can be formed to electrically isolate the first epitaxial structures 2832 and the second epitaxial structures 2834. Each of the first epitaxial growth process and the second epitaxial growth process can include a selective epitaxial growth (SEG) process, CVD deposition techniques (e.g., vapor-phase epitaxy (VPE) and/or ultra-high vacuum CVD (UHV-CVD)), molecular beam epitaxy, or other suitable epitaxial processes. Specifically, the first epitaxial structures 2832 can be grown from the first nanostructures 2806, and the second epitaxial structures 2834 can be grown from the third nanostructures 2810.

The first epitaxial structures 2832 and the second epitaxial structures 2834 may each include silicon germanium (SiGe), indium arsenide (InAs), indium gallium arsenide (InGaAs), indium antimonide (InSb), germanium arsenide (GaAs), germanium antimonide (GaSb), indium aluminum phosphide (InAlP), indium phosphide (InP), any other suitable material, or combinations thereof. Further, in-situ doping (ISD) may be applied during the formation of each of the first epitaxial structures 2832 and the second epitaxial structures 2834. For example, the first epitaxial structures 2832 can be doped by implanting p-type dopants, e.g., boron (B), etc., into them; and the second epitaxial structures 2834 can be doped by implanting n-type dopants, e.g., arsenic (As), phosphorous (P), etc., into them. In some embodiments, the first epitaxial structure 2828 can be coupled to each of the first nanostructures 2806 through a lightly doped region 2833 (e.g., SiGeB); and the second epitaxial structure 2834 can be coupled to each of the third nanostructures 2810 through a lightly doped region 2827 (e.g., SiP).

Corresponding to operation 2720 of FIG. 27, FIG. 37 is a cross-sectional view of the CFET structure 2800 including a first active gate structure 2842 and a second active gate structure 2844, at one of the various stages of fabrication. The cross-sectional view of FIG. 37 is cut along the lengthwise direction of an active region of the CFET structure 2800 (e.g., the X-direction illustrated above).

As shown, the first active gate structure 2842 wraps around each of the first nanostructures 2806; and the second active gate structure 2844 wraps around each of the third nanostructures 2810. To form the first active gate structure 2842 and second active gate structure 2844, the dummy gate structure 2802, and the remaining portions of the sacrificial oxide layers 2824 are removed. As such, a first gate trench, exposing each of the first nanostructures 2806, may be formed in the lower portion 2804-1 (e.g., the first level); and a second gate trench, exposing each of the third nanostructures 2810, may be formed in the upper portion 2804-2 (e.g., the second level). Next, the first active gate structure 2842 can be formed in the first gate trench to wrap around each of the first nanostructures 2806; and the second active gate structure 2844 can be formed in the second gate trench to wrap around each of the third nanostructures 2810.

In some embodiments, the first active gate structure 2842 can include a first gate dielectric and a first gate metal; and the second active gate structure 2844 can include a second gate dielectric and a second gate metal. The first/second gate dielectric may be formed of different high-k dielectric materials or a similar high-k dielectric material. Example high-k dielectric materials include a metal oxide or a silicate of Hf, Al, Zr, La, Mg, Ba, Ti, Pb, and combinations thereof. The first/second gate dielectric may include a stack of multiple high-k dielectric materials. The first gate metal may include one or more p-type work function metals, which may include TiN, TaN, Ru, Mo, Al, WN, ZrSi₂, MoSi₂, TaSi₂, NiSi₂, WN, other suitable p-type work function materials, or combinations thereof; and the second gate metal may include one or more n-type work function metals, may include Ti, Ag, TaAl, TaAlC, TiAlN, TaC, TaCN, TaSiN, Mn, Zr, other suitable n-type work function materials, or combinations thereof.

Upon the first and second active gate structures 2842-2844 being formed, at least one p-type transistor can be formed at the first level, and at least one n-type transistor can be formed at the second level. The p-type transistor can be operatively formed based on the first nanostructures 2806, the gate structure 2842, and the pair of first epitaxial structures 2832, which can, for example, correspond to the nanostructures 1010, gate structure 1020, and epitaxial structures 1014-1016 (FIGS. 10, 14, 24), respectively. The n-type transistor can be operatively formed based on the third nanostructures 2810, the gate structure 2844, and the pair of second epitaxial structures 2834, which can, for example, correspond to the nanostructures 1030, gate structure 1040, and epitaxial structures 1034-1028 (FIGS. 10, 14, 24), respectively.

Corresponding to operation 2718 of FIG. 27, FIG. 38 is a cross-sectional view of the CFET structure 2800 including a first connection structure 2852, a second connection structure 2854, and a third connection structure 2856, at one of the various stages of fabrication. The cross-sectional view of FIG. 38 is cut along the lengthwise direction of an active region of the CFET structure 2800 (e.g., the X-direction illustrated above).

As shown, the first connection structure 2852 is coupled to a corresponding one of the first epitaxial structures 2832; and the second connection structure 2854 is coupled to a corresponding one of the second epitaxial structures 2834. For example, the first connection structure 2852 may be formed below the first epitaxial structure 2828; and the second connection structure 2854 may be formed above the second epitaxial structure 2834. For another example, the first connection structure 2852 may wrap around the first epitaxial structure 2828; and the second connection structure 2854 may wrap around the second epitaxial structure 2834. In some embodiments, the first connection structure 2852 and the second connection structure 2854 may each be configured as MD, as described above, which can include titanium, aluminum, nickel, tungsten, tantalum, or other suitable metal materials. The third connection structure 2856 may correspond to the above-described vertical contact structure (e.g., 660, 1610, 1620) that extends through the second frontside level to allow electrical connection between a first BL and a second BL disposed on the frontside and the backside of the substrate, respectively.

In one aspect of the present disclosure, a device is disclosed. The device includes a substrate having a first side and a second side opposite to each other; a first transistor, a second transistor, a third transistor, and a fourth transistor formed on the first side of the substrate, the first to fourth transistors each formed with a p-type conductivity; a fifth transistor and a sixth transistor formed on the first side of the substrate and over the first to fourth transistors, the fifth to sixth transistors each formed with an n-type conductivity; a first interconnect structure formed on the first side of the substate and over the fifth to sixth transistors, the first interconnect structure coupled to the first transistor, wherein the first interconnect structure is configured as a portion of a first bit line; and a second interconnect structure formed on the second side of the substate, the second interconnect structure also coupled to the first transistor, wherein the second interconnect structure is configured as another portion of the first bit line.

In another aspect of the present disclosure, a semiconductor device is disclosed. The semiconductor device includes a first active region formed on a first side of a substrate and extending along a first lateral direction; a second active region formed on the first side of the substrate and extending along the first lateral direction; a first gate structure formed on the first side of the substrate, extending in a second lateral direction, and traversing the first and second active regions; a second gate structure formed on the first side of the substrate, extending in the second lateral direction, and traversing the first and second active regions; a third active region formed on the first side of the substrate, extending in the first lateral direction, and disposed vertically above and aligned with the first active region; a fourth active region formed on the first side of the substrate, extending in the first lateral direction, and disposed vertically above and aligned with the second active region; a third gate structure formed on the first side of the substrate, extending in the second lateral direction, and disposed vertically above and aligned with the third active region; a fourth gate structure formed on the first side of the substrate, extending in the second lateral direction, and disposed vertically above and aligned with the fourth active region; a first interconnect structure formed on the first side of the substrate, extending in the first lateral direction, and disposed vertically above the third and fourth gate structures; a second interconnect structure formed on the first side of the substrate, extending in the first lateral direction, and disposed vertically above the third and fourth gate structures; a third interconnect structure formed on a second side of the substrate, extending in the first lateral direction, and disposed vertically below the first and second active regions; and a fourth interconnect structure formed on the second side of the substrate, extending in the first lateral direction, and disposed vertically below the first and second active regions. The first to second active regions and the first to second gate structures operatively form first, second, third, and fourth transistors of a memory cell that have a first conductivity, and the third to fourth active regions and the third to fourth gate structures operatively form fifth and sixth transistors of the memory cell that have a second conductivity. The first interconnect structure and the third interconnect structure are electrically coupled to each other through a first contact structure extending in a vertical direction, and the second interconnect structure and the fourth interconnect structure are electrically coupled to each other through a second contact structure extending in the vertical direction.

In yet another aspect of the present disclosure, a method for forming memory devices is disclosed. The method includes forming, on a first side of a substrate, a first active region extending along a first lateral direction. The method includes forming, on the first side of the substrate, a second active region extending along the first lateral direction. The method includes forming, on the first side of the substrate, a first gate structure extending along a second lateral direction and traversing the first and second active regions. The method includes forming, on the first side of the substrate, a second gate structure extending along the second lateral direction and traversing the first and second active regions. The method includes forming, on the first side of the substrate and vertically above the first active region, a third active region extending in the first lateral direction. The method includes forming, on the first side of the substrate and vertically above the second active region, a fourth active region extending along the first lateral direction. The method includes forming, on the first side of the substrate and vertically above the first gate structure, a third gate structure extending along the second lateral direction. The method includes forming, on the first side of the substrate and vertically above the second gate structure, a fourth gate structure extending along the second lateral direction. The method includes forming, on the first side of the substrate, a first interconnect structure extending along the first lateral direction and disposed vertically above the third and fourth gate structures. The method includes forming, on the first side of the substrate, a second interconnect structure extending along the first lateral direction and disposed vertically above the third and fourth gate structures. The method includes forming, on a second side of the substrate, a third interconnect structure extending along the first lateral direction and disposed vertically below the first and second active regions. The method includes forming, on the second side of the substrate, a fourth interconnect structure extending along the first lateral direction and disposed vertically below the first and second active regions. The first interconnect structure and the third interconnect structure are electrically coupled to each other through a first contact structure extending in a vertical direction, and the second interconnect structure and the fourth interconnect structure are electrically coupled to each other through a second contact structure extending in the vertical direction.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A device, comprising:
a substrate having a first side and a second side opposite to each other;
a first transistor, a second transistor, a third transistor, and a fourth transistor formed on the first side of the substrate, the first to fourth transistors each formed with a p-type conductivity;
a fifth transistor and a sixth transistor formed on the first side of the substrate and over the first to fourth transistors, the fifth to sixth transistors each formed with an n-type conductivity;
a first interconnect structure formed on the first side of the substate and over the fifth to sixth transistors, the first interconnect structure coupled to the first transistor, wherein the first interconnect structure is configured as a portion of a first bit line; and
a second interconnect structure formed on the second side of the substate, the second interconnect structure also coupled to the first transistor, wherein the second interconnect structure is configured as another portion of the first bit line.

2. The device of claim 1, wherein the first interconnect structure and the second interconnect structure are in parallel with each other.

3. The device of claim 1, wherein the first to fourth transistors are formed at a first level on the first side, and the fifth and sixth transistors are formed at a second level on the first side.

4. The device of claim 3, further comprising:
a contact structure vertically extending from the first level and further through the second level;
a first via structure disposed above the second level, and connected between the contact structure and the first interconnect structure; and
a second via structure disposed below the first level, and connected between an epitaxial structure of the first transistor and the second interconnect structure.

5. The device of claim 4, wherein the contact structure is configured to electrically couple the first interconnect structure to the second interconnect structure, through at least the first via structure, the epitaxial structure of the first transistor, and the second via structure.

6. The device of claim 1, further comprising:
a third interconnect structure formed on the first side and over the fifth to sixth transistors, the third interconnect structure coupled to the second transistor, wherein the third interconnect structure is configured as a portion of a second bit line; and
a fourth interconnect structure formed on the second side of the substate, the fourth interconnect structure also coupled to the second transistor, wherein the fourth interconnect structure is configured as another portion of the second bit line.

7. The device of claim 6, wherein the third interconnect structure and the fourth interconnect structure are in parallel with and electrically coupled to each other.

8. The device of claim 1, wherein each of the first to sixth transistors has a channel extending along a first lateral direction, and a gate structure extending along a second lateral direction.

9. The device of claim 8, wherein the first and second interconnect structures each extend along the first lateral direction.

10. The device of claim 1, wherein the first to sixth transistors operatively form a Static Random Access Memory (SRAM) cell.

11. The device of claim 10, wherein the first and second transistors each operatively serve as a pass-gate transistor of the SRAM cell, the third and fourth transistors each operatively serve as a pull-up transistor of the SRAM cell, and the fifth and sixth transistors each operatively serve as a pull-down transistor of the SRAM cell.

12. The device of claim 10, wherein the first and second transistors each operatively serve as a pass-gate transistor of the SRAM cell, the third and fourth transistors each operatively serve as a pull-down transistor of the SRAM cell, and the fifth and sixth transistors each operatively serve as a pull-up transistor of the SRAM cell.

13. A semiconductor device, comprising:
a first active region formed on a first side of a substrate and extending along a first lateral direction;
a second active region formed on the first side of the substrate and extending along the first lateral direction;
a first gate structure formed on the first side of the substrate, extending in a second lateral direction, and traversing the first and second active regions;
a second gate structure formed on the first side of the substrate, extending in the second lateral direction, and traversing the first and second active regions;
a third active region formed on the first side of the substrate, extending in the first lateral direction, and disposed vertically above and aligned with the first active region;
a fourth active region formed on the first side of the substrate, extending in the first lateral direction, and disposed vertically above and aligned with the second active region;
a third gate structure formed on the first side of the substrate, extending in the second lateral direction, and disposed vertically above and aligned with the third active region;
a fourth gate structure formed on the first side of the substrate, extending in the second lateral direction, and disposed vertically above and aligned with the fourth active region;
a first interconnect structure formed on the first side of the substrate, extending in the first lateral direction, and disposed vertically above the third and fourth gate structures;
a second interconnect structure formed on the first side of the substrate, extending in the first lateral direction, and disposed vertically above the third and fourth gate structures;
a third interconnect structure formed on a second side of the substrate, extending in the first lateral direction, and disposed vertically below the first and second active regions; and
a fourth interconnect structure formed on the second side of the substrate, extending in the first lateral direction, and disposed vertically below the first and second active regions;
wherein the first to second active regions and the first to second gate structures operatively form first, second, third, and fourth transistors of a memory cell that have a first conductivity, and the third to fourth active regions and the third to fourth gate structures operatively form fifth and sixth transistors of the memory cell that have a second conductivity; and
wherein the first interconnect structure and the third interconnect structure are electrically coupled to each other through a first contact structure extending in a vertical direction, and the second interconnect structure and the fourth interconnect structure are electrically coupled to each other through a second contact structure extending in the vertical direction.

14. The semiconductor device of claim 13, wherein the first interconnect structure and the third interconnect structure are in parallel with each other, and the second interconnect structure and the fourth interconnect structure are in parallel with each other.

15. The semiconductor device of claim 13, wherein the first interconnect structure and the third interconnect structure are electrically coupled to a source/drain terminal of the first transistor, and the second interconnect structure and the fourth interconnect structure are electrically coupled to a source/drain terminal of the second transistor.

16. The semiconductor device of claim 15, wherein the source/drain terminal of the first transistor is formed by a portion of the first active region disposed next to the first gate structure, and the source/drain terminal of the second transistor is formed by a portion of the second active region disposed next to the second gate structure.

17. The semiconductor device of claim 13, wherein the first and second transistors each operatively serve as a pass-gate transistor of the memory cell, the third and fourth transistors each operatively serve as a pull-up transistor of the memory cell, and the fifth and sixth transistors each operatively serve as a pull-down transistor of the memory cell.

18. The semiconductor device of claim 13, wherein the first and second transistors each operatively serve as a pass-gate transistor of the memory cell, the third and fourth transistors each operatively serve as a pull-down transistor of the memory cell, and the fifth and sixth transistors each operatively serve as a pull-up transistor of the memory cell.

19. A method, comprising:
forming, on a first side of a substrate, a first active region extending along a first lateral direction;
forming, on the first side of the substrate, a second active region extending along the first lateral direction;
forming, on the first side of the substrate, a first gate structure extending along a second lateral direction and traversing the first and second active regions;
forming, on the first side of the substrate, a second gate structure extending along the second lateral direction and traversing the first and second active regions;
forming, on the first side of the substrate and vertically above the first active region, a third active region extending in the first lateral direction;
forming, on the first side of the substrate and vertically above the second active region, a fourth active region extending along the first lateral direction;
forming, on the first side of the substrate and vertically above the first gate structure, a third gate structure extending along the second lateral direction;
forming, on the first side of the substrate and vertically above the second gate structure, a fourth gate structure extending along the second lateral direction;
forming, on the first side of the substrate, a first interconnect structure extending along the first lateral direction and disposed vertically above the third and fourth gate structures;
forming, on the first side of the substrate, a second interconnect structure extending along the first lateral direction and disposed vertically above the third and fourth gate structures;
forming, on a second side of the substrate, a third interconnect structure extending along the first lateral direction and disposed vertically below the first and second active regions; and
forming, on the second side of the substrate, a fourth interconnect structure extending along the first lateral direction and disposed vertically below the first and second active regions;
wherein the first interconnect structure and the third interconnect structure are electrically coupled to each other through a first contact structure extending in a vertical direction, and the second interconnect structure and the fourth interconnect structure are electrically coupled to each other through a second contact structure extending in the vertical direction.

20. The method of claim 19, wherein the first to second active regions and the first to second gate structures operatively form first, second, third, and fourth transistors of a memory cell that have a first conductivity, and the third to fourth active regions and the third to fourth gate structures operatively form fifth and sixth transistors of the memory cell that have a second conductivity.
